(19) United States
(12) Patent Application Publication
(10) Pub. No.: US 2023/0335520 A1
(43) Pub. Date: Oct. 19, 2023

(54) NONVOLATILE MEMORY DEVICES, METHODS OF MANUFACTURING NONVOLATILE MEMORY DEVICE, AND ELECTRONIC SYSTEMS INCLUDING NONVOLATILE MEMORY DEVICE

(71) Applicant: Samsung Electronics Co., Ltd., Suwon-si (KR)

(72) Inventors: EUN-JI KIM, Suwon-si (KR); Yoon Jo HWANG, Suwon-si (KR); Seo Jin PARK, Suwon-si (KR); Jun Seok BANG, Suwon-si (KR)

(21) Appl. No.: 18/149,709

(22) Filed: Jan. 4, 2023

(30) Foreign Application Priority Data
Apr. 18, 2022 (KR) 10-2022-0047371

(51) Int. Cl. H01L 23/00; H10B 43/27; H01L 25/065; H01L 25/18; H01L 25/00

(52) U.S. Cl. CPC H01L 24/08; H01L 27/11582; H01L 25/0657; H01L 25/18; H01L 24/80; H01L 25/50; H01L 2224/08145; H01L 2224/80006; H01L 2224/80895; H01L 2224/80896; H01L 2924/1431; H01L 2924/14511

(57) ABSTRACT

Nonvolatile memory devices and methods of forming the same are provided. The devices may include an array region, an extension region, and a pad region and may include a substrate including a source plate. The devices may also include a mold structure that is on a front surface of the substrate and includes gate electrodes and mold insulating films alternately stacked in a stair shape in the extension region, a channel structure extending through the mold structure, a cell contact extending through the mold structure, a first insulator on the mold structure, a second insulator on a rear surface of the substrate, an pad on the second insulator, an contact extending through the first insulator, and a via formed by etching the second insulator and the substrate in the pad region. The source plate does not overlap the cell contact and the contact in a vertical direction.

### CROSS-REFERENCE TO RELATED APPLICATION

This application claims priority to Korean Patent Application No. 10-2022-0047371 filed on Apr. 18, 2022 in the Korean Intellectual Property Office, and all the benefits accruing therefrom under 35 U.S.C. 119, the disclosure of which in its entirety is herein incorporated by reference.

### BACKGROUND

The present disclosure relates to a nonvolatile memory device, a method of manufacturing a nonvolatile memory device, and an electronic system including a nonvolatile memory device.

In order to provide the excellent performance and low price demanded by consumers, there is a need to increase a degree of integration of a nonvolatile memory device. Since a degree of integration of a nonvolatile memory device is one of various factors affecting the price of nonvolatile memory devices, an increased degree of integration is beneficial.

Meanwhile, in the case of two-dimensional or planar nonvolatile memory devices, a degree of integration thereof may be mainly determined by an area occupied by a unit memory cell and thus may be greatly affected by a level of technology for forming fine patterns. However, since ultra-expensive equipment may be used for pattern miniaturization, a degree of integration of a two-dimensional nonvolatile memory device is increasing but is still limited. Accordingly, three-dimensional nonvolatile memory devices including three-dimensionally arranged memory cells have been proposed.

### SUMMARY

Aspects of the present disclosure provide a nonvolatile memory device having improved performance and reliability.

Aspects of the present disclosure also provide an electronic system including a nonvolatile memory device which has improved performance and reliability.

Aspects of the present disclosure also provide a method of manufacturing a nonvolatile memory device having improved performance and reliability.

It should be noted that aspects/objects of the present disclosure are not limited to the above-described aspects/objects, and other aspects/objects of the present disclosure will be apparent to those skilled in the art from the following descriptions.

According to an aspect of the present disclosure, there is provided a nonvolatile memory device comprising, a cell substrate which includes portions respectively included in a cell array region, an extension region, and a pad region of the nonvolatile memory device, the cell substrate including a front surface and a rear surface opposite to each other, and including a common source plate and an insulating pattern, a mold structure on the front surface of the cell substrate and including a plurality of gate electrodes and a plurality of mold insulating films, wherein the plurality of gate electrodes and the plurality of mold insulating films include respective first portions, and the first portions of the plurality of gate electrodes and the first portions of the plurality of mold insulating films are alternately stacked in the cell array region, and wherein the plurality of gate electrodes and the plurality of mold insulating films further include respective second portions, and the second portions of the plurality of gate electrodes and the second portions of the plurality of mold insulating films are alternately stacked in a stair shape in the extension region, a channel structure that extends through the mold structure in the cell array region and is connected to the common source plate, a cell contact that extends through the mold structure in the extension region and is connected to at least one of the plurality of gate electrodes, a first interlayer insulating film that is on the front surface of the cell substrate and extends on (e.g., covers) the mold structure, a second interlayer insulating film on the rear surface of the cell substrate, an input/output pad on the second interlayer insulating film in the pad region, an input/output contact extending through the first interlayer insulating film in the pad region, and an input/output via which is formed by etching the second interlayer insulating film and the cell substrate in the pad region and connects the input/output contact and the input/output pad to each other, wherein the common source plate does not overlap the cell contact and the input/output contact in a first direction that is perpendicular to the front surface of the cell substrate. In some embodiments, the input/output via includes portions respectively in the second interlayer insulating film and the cell substrate in the pad region.

According to another aspect of the present disclosure, there is provided a nonvolatile memory device comprising, a cell structure including a first surface and a second surface opposite to each other, and a peripheral structure bonded to (e.g., contacting) the cell structure and including a third surface bonded to (e.g., contacting) the second surface and a fourth surface opposite to the third surface, wherein the cell structure includes, a cell substrate including portions respectively included in a cell array region, an extension region, and a pad region of the nonvolatile memory device, the cell substrate including a front surface and a rear surface opposite to each other and including a common source plate and an insulating pattern, wherein the front surface of the cell structure faces the peripheral structure, a mold structure on the front surface of the cell substrate and including a plurality of gate electrodes and a plurality of mold insulating films, wherein the plurality of gate electrodes and the plurality of mold insulating films include respective first portions, and the first portions of the plurality of gate electrodes and the first portions of the plurality of mold insulating films are alternately stacked in the cell array region, and wherein the plurality of gate electrodes and the plurality of mold insulating films further include respective second portions, and the second portions of the plurality of gate electrodes and the second portions of the plurality of mold insulating films are alternately stacked in a stair shape in the extension region, a channel structure that extends through the mold structure in the cell array region and is connected to the common source plate, a cell contact that extends through the mold structure in the extension region and is connected to at least one of the plurality of gate electrodes, a first interlayer insulating film that is on the front surface of the cell substrate and extends on (e.g., covers) the mold structure, an input/output contact extending through the first interlayer insulating film in the pad region, a second interlayer insulating film on the rear surface of the cell substrate, a cell pad on the second interlayer insulating film in the cell array region, an extension pad on the second interlayer insulating film in the extension region, an input/output pad on the second interlayer insulating film in the pad region, a cell via that extends through the second interlayer insulating film on the common source plate in the cell array region and connects the common source plate and the cell pad to each other, an extension via which is formed by etching the second interlayer insulating film and the insulating pattern in the extension region and connects the cell contact and the extension pad to each other, and an input/output via which is formed by etching the second interlayer insulating film and the cell substrate in the pad region and connects the input/output contact and the input/output pad to each other, wherein, a bottom surface of the extension via and a bottom surface of the input/output via are between the front surface of the cell substrate and the rear surface of the cell substrate, the insulating pattern overlaps the cell contact and the input/output contact in a first direction that is perpendicular to the front surface of the cell substrate, and the common source plate does not overlap the cell contact and the input/output contact in the first direction. In some embodiments, the extension via includes portions respectively in the second interlayer insulating film and the insulating pattern in the extension region, and the input/output via includes portions respectively in the second interlayer insulating film and the cell substrate in the pad region.

According to another aspect of the present disclosure, there is provided an electronic system comprising, a main board, a nonvolatile memory device on the main board, and a controller electrically connected to the nonvolatile memory device on the main board, wherein the nonvolatile memory device includes a cell substrate including portions respectively included in a cell array region, an extension region, and a pad region, the cell substrate including a front surface and a rear surface opposite to each other and including a common source plate and an insulating pattern, a mold structure on the front surface of the cell substrate and including a plurality of gate electrodes and a plurality of mold insulating films, wherein the plurality of gate electrodes and the plurality of mold insulating films include respective first portions, and the first portions of the plurality of gate electrodes and the first portions of the plurality of mold insulating films are alternately stacked in the cell array region, and wherein the plurality of gate electrodes and the plurality of mold insulating films further include respective second portions, and the second portions of the plurality of gate electrodes and the second portions of the plurality of mold insulating films are alternately stacked in a stair shape in the extension region, a channel structure that extends through the mold structure in the cell array region and is connected to the common source plate, a cell contact that extends through the mold structure in the extension region and is connected to at least one of the plurality of gate electrodes, a first interlayer insulating film that is on the front surface of the cell substrate and extends on (e.g., covers) the mold structure, a second interlayer insulating film on the rear surface of the cell substrate, an input/output pad on the second interlayer insulating film in the pad region, an input/output contact extending through the first interlayer insulating film in the pad region, and an input/output via which is formed by etching the second interlayer insulating film and the cell substrate in the pad region and connects the input/output contact and the input/output pad to each other, wherein the insulating pattern does not overlap the cell contact and the input/output contact in a vertical direction. In some embodiments, the input/output via that includes portions respectively in the second interlayer insulating film and the cell substrate in the pad region.

According to another aspect of the present disclosure, there is provided a method of manufacturing a nonvolatile memory device, the method comprising, providing a pre-cell substrate including a front surface and a rear surface opposite to each other, forming a mold structure including a plurality of mold insulating films and a plurality of gate electrodes alternately stacked, on the front surface of the pre-cell substrate, forming an interlayer insulating film extending on (e.g., covering) the mold structure, forming a cell contact that extends through the mold structure and is connected to at least one of the plurality of gate electrodes, wherein an upper surface of the cell contact is provided between the front surface and the rear surface of the pre-cell substrate, forming an input/output contact that extends through the interlayer insulating film, wherein an upper surface of the input/output contact is between the front surface and the rear surface of the pre-cell substrate, removing the pre-cell substrate to form a cell substrate, wherein the cell substrate includes a front surface and a rear surface opposite to each other and includes a common source plate and an insulating pattern, the common source plate does not overlap the input/output contact and the cell contact in a first direction that is perpendicular to the front surface of the cell substrate, and the insulating pattern overlaps the input/output contact and the cell contact in the first direction, and etching the cell substrate to form an input/output via connected to the input/output contact, wherein a bottom surface of the input/output via is between the front surface and the rear surface of the cell substrate. In some embodiments, forming the input/output via may include etching the cell substrate to form an opening and then forming the input/output via in the opening.

### BRIEF DESCRIPTION OF THE DRAWINGS

The above and other aspects and features of the present disclosure will become more apparent by describing example embodiments thereof in detail with reference to the attached drawings, in which:

FIG. 1 is a block diagram of a nonvolatile memory device according to some example embodiments.

FIG. 2 is a circuit diagram of a nonvolatile memory device according to some example embodiments.

FIG. 3 is a layout of a nonvolatile memory device according to some example embodiments.

FIG. 4 is a cross-sectional view taken along the line A-A′ of FIG. 3.

FIG. 5 is a cross-sectional view taken along the line B-B′ of FIG. 3.

FIG. 6 is an enlarged cross-sectional view of the region P of FIG. 5.

FIG. 7 is an enlarged cross-sectional view of the region Q of FIG. 4.

FIGS. 8 to 11 are views of nonvolatile memory devices according to some example embodiments.

FIGS. 12 and 13 are views of nonvolatile memory devices according to some example embodiments.

FIGS. 14 to 27 are views illustrating processes of manufacturing a nonvolatile memory device according to some example embodiments.

FIG. 28 is a block diagram of an electronic system according to some example embodiments.

FIG. 29 is a perspective view of an electronic system according to some example embodiments.

FIG. 30 is a schematic cross-sectional view taken along the line I-I of FIG. 29.

### DETAILED DESCRIPTION

Hereinafter, in order to describe the present invention in more detail, some example embodiments of the present invention will be described in more detail with reference to the accompanying drawings.

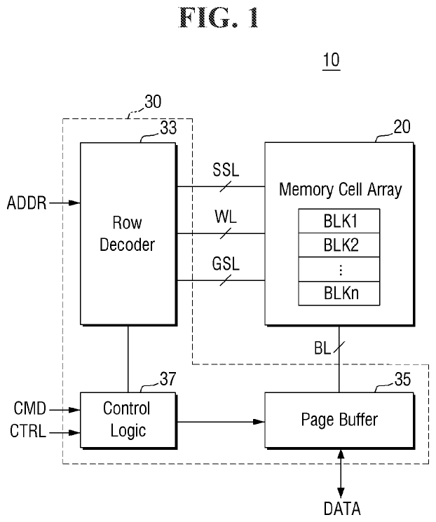

Hereinafter, a nonvolatile memory device according to example embodiments will be described with reference to FIGS. 1 to 13.

FIG. 1 is a block diagram of a nonvolatile memory device according to some example embodiments.

Referring to FIG. 1, a nonvolatile memory device 10 according to some example embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL, and the ground selection line GSL. In addition, the memory cell blocks BLK1 to BLKn may be connected to a page buffer 35 through the bit line BL.

The peripheral circuit 30 may receive an address ADDR, a command CMD, and a control signal CTRL from a device outside the nonvolatile memory device 10 and may transmit or receive data DATA to or from the device outside the nonvolatile memory device 10. The peripheral circuit 30 may include a control logic 37, the row decoder 33, and the page buffer 35. Although not shown, the peripheral circuit 30 may further include various sub-circuits such as an input/output circuit, a voltage generation circuit configured to generate various voltages necessary for the operation of the nonvolatile memory device 10, and an error correction circuit configured to correct an error in the data DATA read from the memory cell array 20.

The control logic 37 may be connected to the row decoder 33, the input/output circuit, and the voltage generation circuit. The control logic 37 may control the overall operation of the nonvolatile memory device 10. The control logic 37 may generate various internal control signals used in the nonvolatile memory device 10 in response to a control signal CTRL. For example, when a memory operation such as a program operation or an erase operation is performed, the control logic 37 may adjust a level of a voltage provided to the word line WL and the bit line BL.

The row decoder 33 may select at least one of the plurality of memory cell blocks BLK1 to BLKn in response to the address ADDR and may select at least one word line WL, at least one string selection line SSL, and at least one ground selection line GSL of the selected one of the memory cell blocks BLK1 to BLKn. In addition, the row decoder 33 may transmit a voltage for performing a memory operation to the selected word line WL of the memory cell blocks BLK1 to BLKn.

The page buffer 35 may be connected to the memory cell array 20 through the bit line BL. The page buffer 35 may operate as a write driver or a sense amplifier. Specifically, when a program operation is performed, the page buffer 35 operates as the write driver to apply a voltage according to the data DATA, which is to be stored in the memory cell array 20, to the bit line BL. Meanwhile, when a read operation is performed, the page buffer 35 may operate as the sense amplifier to detect the data DATA stored in the memory cell array 20.

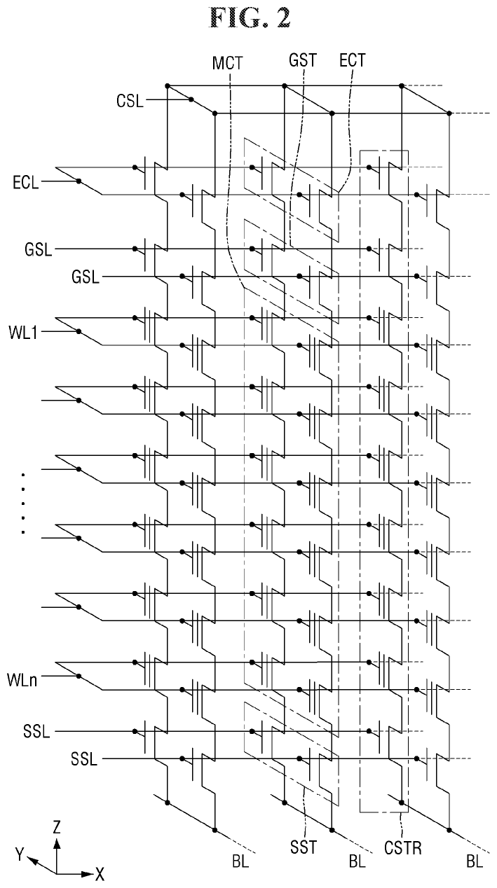

FIG. 2 is a circuit diagram for describing a nonvolatile memory device according to some example embodiments.

Referring to FIG. 2, a memory cell array (for example, the memory cell array 20 of FIG. 1) of the nonvolatile memory device according to some example embodiments may include a common source line CSL, a plurality of bit lines BL, and a plurality of cell strings CSTR.

The common source line CSL may extend in a first direction X. In some example embodiments, a plurality of common source lines CSL may be two-dimensionally arranged. For example, the plurality of common source lines CSL may be spaced from each other and each extend in the first direction X. The same voltage may be electrically applied to the common source lines CSL, or different voltages may be applied to separately control the common source lines CSL. As used herein, “an element A extends in a direction X” (or similar language) means that the element A extends longitudinally in the direction X.

The plurality of bit lines BL may be two-dimensionally arranged. For example, the bit lines BL may be spaced from each other and each extend in a second direction Y intersecting the first direction X. The plurality of cell strings CSTR may be connected in parallel to the bit lines BL. The cell strings CSTR may be commonly connected to the common source line CSL. That is, the plurality of cell strings CSTR may be disposed between the bit lines BL and the common source line CSL.

Each of the cell strings CSTR may include a ground selection transistor GST connected to the common source line CSL, a string selection transistor SST connected to the bit line BL, and a plurality of memory cell transistors MCT disposed between the ground selection transistor GST and the string selection transistor SST. Each of the memory cell transistors MCT may include a data storage element. The ground selection transistor GST, the string selection transistor SST, and the memory cell transistors MCT may be connected in series in a third direction Z. In some embodiments, the first direction X, the second direction Y, and the third direction Z may be substantially perpendicular to each other.

The common source line CSL may be commonly connected to sources of the ground selection transistors GST. In addition, a ground selection line GSL, a plurality of word lines WL1 to WLn, and a string selection line SSL may be disposed between the common source line CSL and the bit line BL. The ground selection line GSL may be used as a gate electrode of the ground selection transistor GST, the word lines WL1 to WLn may be used as gate electrodes of the memory cell transistors MCT, and the string selection line SSL may be used as a gate electrode of the string selection transistor SST.

In some example embodiments, an erase control transistor ECT may be disposed between the common source line CSL and the ground selection transistor GST. The common source line CSL may be commonly connected to sources of the erase control transistors ECT. In addition, an erase control line ECL may be disposed between the common source line CSL and the ground selection line GSL. The erase control line ECL may be used as a gate electrode of the erase control transistor ECT. The erase control transistor ECT may generate a gate induced drain leakage (GIDL) to perform an erase operation of the memory cell array.

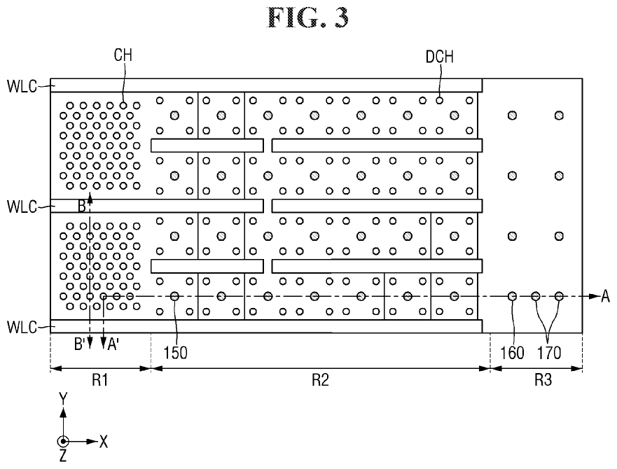

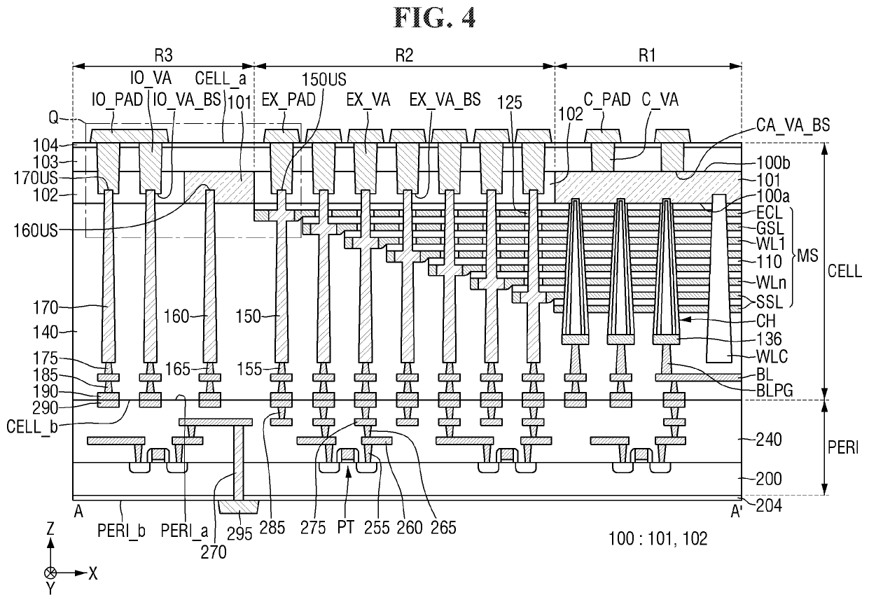

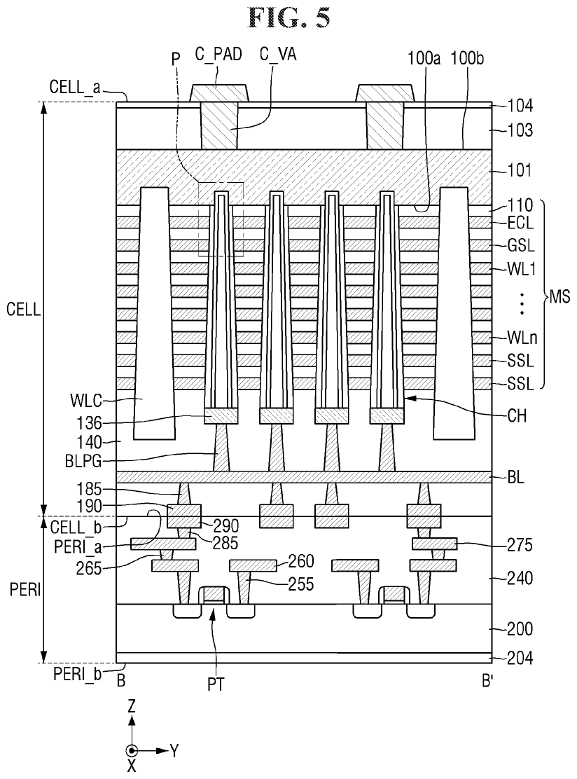

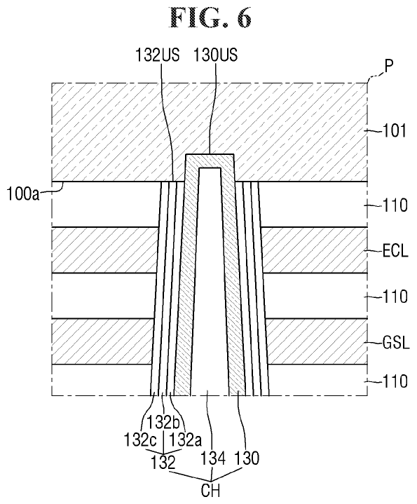

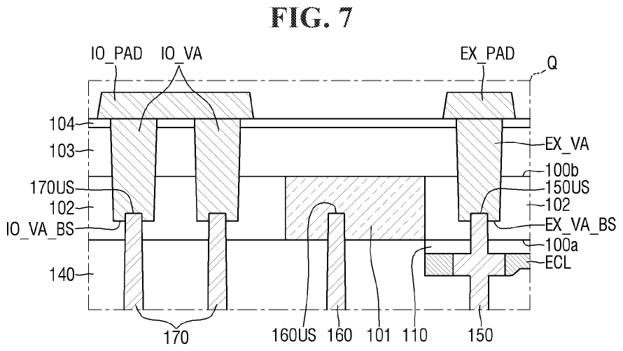

FIG. 3 is a layout of a nonvolatile memory device according to some example embodiments. FIG. 4 is a cross-sectional view taken along the line A-A′ of FIG. 3. FIG. 5 is a cross-sectional view taken along the line B-B′ of FIG. 3. FIG. 6 is an enlarged cross-sectional view of the region P of FIG. 5. FIG. 7 is an enlarged cross-sectional view of the region Q of FIG. 4.

Referring to FIGS. 3 to 7, the nonvolatile memory device according to some example embodiments includes a cell structure CELL and a peripheral structure PERI.

The nonvolatile memory device according to some example embodiments may have a chip-to-chip (C2C) structure. The C2C structure may be a structure in which an upper chip including the cell structure CELL is manufactured on a first wafer, a lower chip including the peripheral structure PERI is manufactured on a second wafer different from the first wafer, and then the upper chip and the lower chip are connected to each other through a bonding method. As an example, the bonding method may be a method of electrically connecting a bonding metal formed on an uppermost metal layer of the upper chip and a bonding metal formed on an uppermost metal layer of the lower chip to each other. For example, when the bonding metal is formed of copper (Cu), the bonding method may be a Cu—Cu bonding method, and the bonding metal may be formed of aluminum or tungsten.

More specifically, the cell structure CELL may include a first surface CELL_a and a second surface CELL_b which are opposite to each other. The peripheral structure PERI may include a third surface PERI_a and a fourth surface PERI_b which are opposite to each other. The second surface CELL_b of the cell structure CELL may face the third surface PERI_a of the peripheral structure PERI. The second surface CELL_b of the cell structure CELL and the third surface PERI_a of the peripheral structure PERI may contact (e.g., be bonded to) each other. Thus, the cell structure CELL and the peripheral structure PERI may be bonded to each other.

In some example embodiments, the cell structure CELL may include a cell substrate 100, a mold structure MS, a first interlayer insulating film 140, a second interlayer insulating film 103, an upper insulating film 104, a channel structure CH, a word line cutting structure WLC, a bit line BL, a cell contact 150, a source contact 160, and a first input/output contact 170.

The nonvolatile memory device according to some example embodiments may include a cell array region R1, an extension region R2, and a pad region R3. A memory cell array (for example, the memory cell array 20 of FIG. 1) including a plurality of memory cells may be formed in the cell array region R1. For example, the channel structure CH, the bit line BL, and gate electrodes ECL, GSL, WL1 to WLn, and SSL, which will be described below, may be disposed in the cell array region R1.

The extension region R2 may be disposed around the cell array region R1. The gate electrodes ECL, GSL, WL1 to WLn, and SSL, which will be described below, may be stacked in a stair shape in the extension region R2.

The pad region R3 may be disposed inside the cell array region R1 and the extension region R2 or may be disposed outside the cell array region R1 and the extension region R2. The source contact 160, the first input/output contact 170, and the like, which will be described below, may be disposed in the pad region R3.

The cell substrate 100 may include a common source plate 101 and an insulating pattern 102. The common source plate 101 may be provided in the cell array region R1 and a portion of the pad region R3. The common source plate 101 may not be provided in the extension region R2. The common source plate 101 may be connected to the channel structure CH and the source contact 160.

For example, the common source plate 101 may be connected to a semiconductor pattern 130 of the channel structure CH in the cell array region R1. The common source plate 101 may be connected to the source contact 160 in the pad region R3. The common source plate 101 may be provided as a common source line (for example, the common source line CSL of FIG. 2) of the nonvolatile memory device. The common source plate 101 may include, for example, polysilicon doped with impurities and/or a metal, but the present disclosure is not limited thereto.

In some example embodiments, the common source plate 101 may not overlap the cell contact 150 and the first input/output contact 170 in a third direction Z. As used herein, “an element A overlapping an element B in a direction X” (or similar language) means that there is at least one line that extends in the direction X and intersects both the elements A and B.

The insulating pattern 102 may be provided in the extension region R2 and a portion of the pad region R3. The insulating pattern 102 may not be provided in the cell array region R1. The insulating pattern 102 may surround a portion of the cell contact 150 and a portion of the first input/output contact 170. The insulating pattern 102 may overlap the cell contact 150 and the first input/output contact 170 in the third direction Z. In addition, the insulating pattern 102 may cover portions of an extension via EX_VA and an input/output via IO_VA which will be described below.

The insulating pattern 102 may include an oxide-based insulating material. For example, the insulating pattern 102 may include silicon oxide (SiO₂). Specifically, the insulating pattern 102 may include, for example, flowable oxide (FOX), tonen silazen (TOSZ), undoped silica glass (USG), borosilica glass (BSG), phosphor silica glass (PSG), borophosphosilica glass (BPSG), plasma enhanced tetra ethyl ortho silicate (PE-TEOS), fluoride silicate glass (FSG), high density plasma (HDP), plasma enhanced oxide (PEOX), flowable chemical vapor deposition (FCVD) oxide, or a combination thereof.

The cell substrate 100 may include a front surface 100a and a rear surface 100b which are opposite to each other. The front surface 100a of the cell substrate 100 may face the peripheral structure PERI. The rear surface 100b of the cell substrate 100 may be opposite to the peripheral structure PERI. A front surface of the common source plate 101 and a front surface of the insulating pattern 102 may be portions of the front surface 100a of the cell substrate 100. A rear surface of the common source plate 101 and a rear surface of the insulating pattern 102 may be portions of the rear surface 100b of the cell substrate 100.

The mold structure MS may be provided on the front surface 100a of the cell substrate. The mold structure MS may include a plurality of gate electrodes ECL, GSL, WL1 to WLn, and SSL and a plurality of mold insulating films 110 which are alternately stacked on the cell substrate 100. Each of the gate electrodes ECL, GSL, WL1 to WLn, and SSL and each of the mold insulating films 110 may have a layered structure extending parallel to the front surface 100a of the cell substrate 100. The gate electrodes ECL, GSL, WL1 to WLn, and SSL are spaced from each other by the mold insulating films 110 and may be sequentially stacked on the cell substrate 100.

The gate electrodes ECL, GSL, WL1 to WLn, and SSL may be stacked in a stair shape in the extension region R2. For example, the gate electrodes ECL, GSL, WL1 to WLn, and SSL may extend to have different lengths in a first direction X and have a step difference. In some example embodiments, the gate electrodes ECL, GSL, WL1 to WLn, and SSL may have a step difference in a second direction Y. Accordingly, the gate electrodes ECL, GSL, WL1 to WLn, and SSL may include exposed regions exposed from other gate electrodes. In some embodiments, each of the gate electrodes ECL, GSL, WL1 to WLn, and SSL may include a portion that an adjacent electrode does not overlap in the third direction Z, as illustrated in FIG. 4. The exposed regions may be regions in which the cell contacts 150 are in contact with the gate electrodes ECL, GSL, WL1 to WLn, and SSL.

Heights of the gate electrodes ECL, GSL, WL1 to WLn, and SSL, which are in contact with the cell contacts 150 in the exposed regions, in the third direction Z may be greater than heights of other gate electrodes ECL, GSL, WL1 to WLn, and SSL in the third direction Z. The third direction Z may be a direction perpendicular to the front surface 100a of the cell substrate 100. Accordingly, a width of a contact area between the cell contacts 150 and the gate electrodes ECL, GSL, WL1 to WLn, and SSL may be increased. However, embodiments of the present disclosure are not limited thereto.

In some example embodiments, the gate electrodes ECL, GSL, WL1 to WLn, and SSL may include an erase control line ECL, a ground selection line GSL, and a plurality of word lines WL1 to WLn which are sequentially stacked on the cell substrate 100. In some other embodiments, the erase control line ECL may be omitted.

The mold insulating films 110 may be stacked in a stair shape in the extension region R2. For example, the mold insulating films 110 may extend to have different lengths in the first direction X and have a step difference. In some example embodiments, the mold insulating films 110 may have a step difference in the second direction Y.

Each of the gate electrodes ECL, GSL, WL1 to WLn, and SSL may include a conductive material, for example, a metal such as tungsten (W), cobalt (Co), or nickel (Ni), or a semiconductor material such as silicon. However, the present disclosure is not limited thereto. As an example, each of the gate electrodes ECL, GSL, WL1 to WLn, and SSL may include tungsten (W). Unlike what is shown in the drawing, each of the gate electrodes ECL, GSL, WL1 to WLn, and SSL may be a multi-film layer. For example, when each of the gate electrodes ECL, GSL, WL1 to WLn, and SSL is a multi-film layer, each of the gate electrodes ECL, GSL, WL1 to WLn, and SSL may include a gate electrode barrier film and a gate electrode filling film. The gate electrode barrier film may include, for example, titanium nitride (TiN), and the gate electrode filling film may include tungsten (W), but the present disclosure is not limited thereto.

The mold insulating film 110 may include an insulating material, for example, at least one selected from among silicon oxide, silicon nitride, and silicon oxynitride, but the present disclosure is not limited thereto. As an example, the mold insulating film 110 may include silicon oxide.

The first interlayer insulating film 140 may be provided on the front surface 100a of the cell substrate 100. The first interlayer insulating film 140 may cover the mold structure MS. The first interlayer insulating film 140 may include an oxide-based insulating material. The first interlayer insulating film 140 may include, for example, at least one selected from among silicon oxide, silicon oxynitride, and a low-k material having a dielectric constant that is lower than that of silicon oxide, but the present disclosure is not limited thereto.

The channel structure CH may be provided in the mold structure MS of the cell array region R1. The channel structure CH may extend in the third direction Z intersecting the front surface 100a of the cell substrate 100 to pass through the mold structure MS. For example, the channel structure CH may have a pillar shape (for example, a cylindrical shape) extending in the third direction Z. Accordingly, the channel structure CH may intersect each of the gate electrodes ECL, GSL, WL1 to WLn, and SSL.

The channel structure CH may include the semiconductor pattern 130 and an information storage film 132.

The semiconductor pattern 130 may extend in the third direction Z to pass through the mold structure MS. The semiconductor pattern 130 is illustrated to have only a cup shape, but this is merely an example. For example, the semiconductor pattern 130 may have any shape such as a cylindrical shape, a quadrangular tubular shape, or a solid filler shape. The semiconductor pattern 130 may include, for example, a semiconductor material such as single crystal silicon, polycrystalline silicon, an organic semiconductor material, or a carbon nanostructure, but the present disclosure is not limited thereto.

The information storage film 132 may be interposed between the semiconductor pattern 130 and each of the gate electrodes ECL, GSL, WL1 to WLn, and SSL. For example, the information storage film 132 may extend along an outer surface of the semiconductor pattern 130. The information storage film 132 may include, for example, at least one selected from among silicon oxide, silicon nitride, silicon oxynitride, and a high-k material having a dielectric constant that is higher than that of silicon oxide. The high-k material may include, for example, at least one selected from among aluminum oxide, hafnium oxide, lanthanum oxide, tantalum oxide, titanium oxide, lanthanum hafnium oxide, lanthanum aluminum oxide, dysprosium scandium oxide, and a combination thereof.

In some example embodiments, a plurality of channel structures CH may be arranged in a zigzag shape. For example, as shown in FIG. 3, the plurality of channel structures CH may be alternately arranged in the first direction X and the second direction Y. The plurality of channel structures CH arranged in a zigzag pattern can further increase a degree of integration of the nonvolatile memory device. In some example embodiments, the plurality of channel structures CH may be arranged in a honeycomb shape.

In some example embodiments, dummy channel structures DCH may be formed in the mold structure MS of the extension region R2. The dummy channel structure DCH may be formed in a shape similar to that of the channel structure CH to reduce stress applied to the mold structure MS in the extension region R2.

In some example embodiments, the information storage film 132 may be formed as a multi-film layer. For example, as shown in FIG. 6, the information storage film 132 may include a tunnel insulating film 132a, a charge storage film 132b, and a blocking insulating film 132c which are sequentially stacked on the outer surface of the semiconductor pattern 130.

The tunnel insulating film 132a may include, for example, silicon oxide or a high-k material (for example, aluminum oxide (Al₂O₃) or hafnium oxide (HfO₂)) having a dielectric constant that is higher than that of silicon oxide. The charge storage film 132b may include, for example, silicon nitride. The blocking insulating film 132c may include, for example, silicon oxide or a high-k material (for example, aluminum oxide (Al₂O₃) or hafnium oxide (HfO₂)) having a dielectric constant that is higher than that of silicon oxide.

In some example embodiments, the channel structure CH may further include a filling pattern 134. The filling pattern 134 may be formed to fill the inside of the semiconductor pattern 130 having the cup shape. The filling pattern 134 may include an insulating material, for example, silicon oxide, but the present disclosure is not limited thereto.

In some example embodiments, the channel structure CH may further include a channel pad 136. The channel pad 136 may be formed to be connected to the semiconductor pattern 130. For example, the channel pad 136 may be provided in the first interlayer insulating film 140 and connected to an upper portion of the semiconductor pattern 130. The channel pad 136 may include, for example, polysilicon doped with impurities, but the present disclosure is not limited thereto.

In some example embodiments, the semiconductor pattern 130 may be connected to the common source plate 101 in the cell array region R1. A portion of the semiconductor pattern 130 may overlap the common source plate 101 in the first direction X and the second direction Y. An upper surface 130US of the semiconductor pattern 130 may be provided between the front surface 100a and the rear surface 100b of the cell substrate 100. The upper surface 130US of the semiconductor pattern 130 may be opposite to the peripheral structure PERI. A portion of the semiconductor pattern 130 may be provided in the common source plate 101. The upper surface 130US of the semiconductor pattern 130 may be in contact with the common source plate 101. A portion of a side surface of the semiconductor pattern 130 may be in contact with the common source plate 101.

In some example embodiments, an upper surface 132US of the information storage film 132 may be coplanar with the front surface 100a of the cell substrate 100. The upper surface 132US of the information storage film 132 may be opposite to the peripheral structure PERI. The information storage film 132 may not be provided in the common source plate 101. The information storage film 132 may not overlap the common source plate 101 in the first direction X and the second direction Y. In some embodiments, the information storage film 132 may not include a portion that is provided in the common source plate 101. However, embodiments of the present disclosure are not limited thereto.

The word line cutting structure WLC may extend in the first direction X to cut the mold structure MS. The mold structure MS may be cut by a plurality of word line cutting structures WLC to form a plurality of memory cell blocks (for example, BLK1 to BLKn of FIG. 1). For example, two adjacent word line cutting structures WLC may define one memory cell block therebetween. The plurality of channel structures CH may be disposed in each of the memory cell blocks defined by the word line cutting structures WLC.

In FIG. 3, only nine channel structures CH are illustrated as being arranged in a zigzag pattern in the second direction Y in one memory cell block, but this is merely an example. Of course, the number of channel structures CH disposed in each memory cell block is not limited to the illustrated number and may vary.

In some example embodiments, the word line cutting structure WLC may extend in the first direction X to cut the mold insulating films 110 and the gate electrodes ECL, GSL, WL1 to WLn, and SSL. The word line cutting structure WLC may include an insulating material. For example, the insulating material may fill the word line cutting structure WLC. The insulating material may include an insulating material, for example, at least one selected from among silicon oxide, silicon nitride, and silicon oxynitride, but the present disclosure is not limited thereto.

The bit line BL may be formed in the mold structure MS and the first interlayer insulating film 140. The bit line BL may extend in the second direction Y to intersect the word line cutting structure WLC. In addition, the bit line BL may extend in the second direction Y to be connected to the plurality of channel structures CH arranged in the second direction Y. For example, bit line contact plugs BLPG connected to upper portions of the channel structures CH may be formed in the first interlayer insulating film 140. The bit line BL may be electrically connected to the channel structures CH through the bit line contact plugs BLPG.

The cell contact 150 may be provided in the extension region R2. The cell contact 150 may extend in the third direction Z in the extension region R2 to pass through the first interlayer insulating film 140 and the mold structure MS. The cell contact 150 may be connected to one of the gate electrodes ECL, GSL, WL1 to WLn, and SSL in the extension region R2. The cell contact 150 may be in contact with a gate electrode disposed at an uppermost side among the gate electrodes ECL, GSL, WL1 to WLn, and SSL stacked in the stair shape.

For example, the cell contact 150 may be in contact with a sidewall of the gate electrode disposed at the uppermost side. The gate electrode disposed at the uppermost side may be a gate electrode in contact with the first interlayer insulating film 140. A thickness (e.g., a width in the third direction Z) of the sidewall of the gate electrode in contact with the cell contact 150 may be greater than a thickness (e.g., a width in the third direction Z) of a sidewall of the gate electrode not in contact with the cell contact 150, but embodiments of the present disclosure are not limited thereto. For convenience of description, seven cell contacts 150 are illustrated, but the present disclosure is not limited thereto.

In some example embodiments, an upper surface 150US of the cell contact 150 may be disposed in the insulating pattern 102. That is, the upper surface 150US of the cell contact 150 may be provided between the front surface 100a and the rear surface 100b of the cell substrate 100. The cell contact 150 may not overlap the common source plate 101 in the third direction Z. A portion of the cell contact 150 may overlap the common source plate 101 in the first direction X and the second direction Y. The common source plate 101 may include a portion that does not overlap the cell contact 150 in the first direction X and the second direction Y. That is, the cell contact 150 does not completely pass through the cell substrate 100.

In some example embodiments, the cell contact 150 may be electrically connected to the bit line BL through a first contact 155. The first contact 155 may include a conductive material. The first contact 155 may include, for example, tungsten (W) or copper (Cu), but the present disclosure is not limited thereto.

The cell contact 150 may include a conductive material. The cell contact 150 may include, for example, a metal such as tungsten (W), cobalt (Co), or nickel (Ni), but the present disclosure is not limited thereto. As an example, the cell contact 150 may include tungsten (W).

Insulating rings 125 may be provided in the mold structure MS. The insulating ring 125 may be interposed between the cell contact 150 and each of the gate electrodes ECL, GSL, WL1 to WLn, and SSL. The insulating ring 125 may electrically insulate the cell contact 150 from some of the gate electrodes ECL, GSL, WL1 to WLn, and SSL. For example, the insulating ring 125 may be an annular structure surrounding the cell contact 150.

The insulating ring 125 may electrically insulate other gate electrodes not exposed in the exposed regions among the gate electrodes ECL, GSL, WL1 to WLn, and SSL from the cell contacts 150. As an example, except for the gate electrode at the uppermost side connected to the cell contact 150, the insulating ring 125 may prevent gate electrodes from coming in contact with the cell contacts 150.

The insulating ring 125 may include an insulating material. The insulating ring 125 may include, for example, an oxide-based insulating material. As an example, the insulating ring 125 may include silicon oxide, but the present disclosure is not limited thereto.

The source contact 160 may be provided in the pad region R3. The source contact 160 may be formed of a conductive material such as a metal, a metal compound, or polysilicon and may be electrically connected to the common source plate 101. The source contact 160 may be electrically connected to the bit line BL through a second contact 165. The second contact 165 may include a conductive material. The second contact 165 may include, for example, tungsten (W) or copper (Cu), but the present disclosure is not limited thereto.

In some example embodiments, an upper surface 160US of the source contact 160 may be provided between the front surface 100a and the rear surface 100b of the cell substrate 100. The source contact 160 does not overlap the insulating pattern 102 in the third direction Z. The source contact 160 includes a portion that overlaps the insulating pattern 102 in the first direction X and the second direction Y. The insulating pattern 102 includes a portion that does not overlap the source contact 160 in the first direction X and the second direction Y. That is, the source contact 160 does not completely pass through the cell substrate 100.

The first input/output contact 170 may pass through the first interlayer insulating film 140 to be connected to a first input/output pad IO_PAD which will be described below. The first input/output contact 170 may be provided in the pad region R3. According to some example embodiments, the common source plate 101 may not be disposed in a region in which the first input/output contact 170 is disposed. The insulating pattern 102 may be disposed in a region in which the first input/output contact 170 is disposed. The first input/output contact 170 and the common source plate 101 may not overlap each other in the third direction Z. The first input/output contact 170 may overlap the insulating pattern 102 in the third direction Z.

In addition, the first input/output pad IO_PAD may not overlap the gate electrodes ECL, GSL, WL1 to WLn, and SSL in the third direction Z. The first input/output contact 170 may be electrically connected to the bit line BL through a third contact 175. The third contact 175 may include a conductive material. The third contact 175 may include, for example, tungsten (W) or copper (Cu), but the present disclosure is not limited thereto.

The second interlayer insulating film 103 may be provided on the rear surface 100b of the cell substrate 100. The second interlayer insulating film 103 may include an oxide-based insulating material. For example, the second interlayer insulating film 103 may include silicon oxide (SiO₂). Specifically, the second interlayer insulating film 103 may include, for example, FOX, TOSZ, USG, BSG, PSG, BPSG, PE-TEOS, FSG, HDP, PEOX, FCVD oxide, or a combination thereof.

The upper insulating film 104 may be provided on the second interlayer insulating film 103. The upper insulating film 104 may include a material having an etch selectivity with respect to the second interlayer insulating film 103. The upper insulating film 104 may include, for example, silicon nitride (SiN), but the present disclosure is not limited thereto.

The nonvolatile memory device according to some example embodiments may further include the first input/output pad IO_PAD, an extension pad EX_PAD, a cell pad C_PAD, an input/output via IO_VA, an extension via EX_VA, and a cell via C_VA.

The first input/output pad IO_PAD may be provided on the upper insulating film 104 of the pad region R3. The first input/output pad IO_PAD may be connected to the input/output via IO_VA and the first input/output contact 170. The first input/output pad IO_PAD may be electrically connected to the peripheral structure PERI through the first input/output contact 170 and the input/output via IO_VA. In addition, the first input/output pad IO_PAD may electrically connect an external device and the nonvolatile memory device to each other. The first input/output pad IO_PAD may include a conductive material. As an example, the first input/output pad IO_PAD may include aluminum (Al), but the present disclosure is not limited thereto.

The extension pad EX_PAD may be provided on the upper insulating film 104 of the extension region R2. The extension pad EX_PAD may be connected to the extension via EX_VA and the cell contact 150. The extension pad EX_PAD may be electrically connected to the bit line BL through the cell contact 150 and the extension via EX_VA. The extension pad EX_PAD may include a conductive material. As an example, the extension pad EX_PAD may include aluminum (Al), but the present disclosure is not limited thereto.

The cell pad C_PAD may be provided on the upper insulating film 104 of the cell array region R1. The cell pad C_PAD may be connected to the cell via C_VA and the common source plate 101. The cell pad C_PAD may be electrically connected to the common source plate 101 through the cell via C_VA. The cell pad C_PAD may include a conductive material. For example, the cell pad C_PAD may include aluminum (Al), but the present disclosure is not limited thereto.

The input/output via IO_VA may pass through the upper insulating film 104 and the second interlayer insulating film 103 and may be provided by etching a portion of the insulating pattern 102. The input/output via IO_VA may be provided in the pad region R3. The input/output via IO_VA does not overlap the common source plate 101 in the third direction Z. The input/output via IO_VA overlaps the insulating pattern 102 in the pad region R3 in the third direction Z. A portion of the input/output via IO_VA may overlap the common source plate 101 in the first direction X and the second direction Y. A portion of the common source plate 101 may not overlap the input/output via IO_VA in the first direction X and the second direction Y. That is, the input/output via IO_VA may not completely pass through the cell substrate 100.

The input/output via IO_VA may electrically connect the first input/output contact 170 and the first input/output pad IO_PAD to each other. The first input/output contact 170 and the first input/output pad IO_PAD may not be directly connected. That is, the first input/output contact 170 and the first input/output pad IO_PAD may be electrically connected to each other through the input/output via IO_VA.

A portion of the input/output via IO_VA may be provided in the insulating pattern 102 of the pad region R3. For example, as shown in FIG. 7, a bottom surface IO_VA_BS of the input/output via IO_VA may be provided between the front surface 100a and the rear surface 100b of the cell substrate 100.

In some example embodiments, a portion of the input/output via IO_VA may surround a portion of the first input/output contact 170. As an example, a level of the bottom surface IO_VA_BS of the input/output via IO_VA may be different from a level of an upper surface 170US of the first input/output contact 170. A height from the rear surface 100b of the cell substrate 100 to the bottom surface IO_VA_BS of the input/output via IO_VA may be greater than a height from the rear surface 100b of the cell substrate 100 to the upper surface 170US of the first input/output contact 170. However, embodiments of the present disclosure are not limited thereto.

The extension via EX_VA may pass through the upper insulating film 104 and the second interlayer insulating film 103 and may be provided by etching a portion of the insulating pattern 102. The extension via EX_VA may be provided in the extension region R2. The extension via EX_VA does not overlap the common source plate 101 in the third direction Z. The extension via EX_VA overlaps the insulating pattern 102 in the third direction Z. A portion of the extension via EX_VA may overlap the common source plate 101 in the first direction X and the second direction Y. A portion of the common source plate 101 may not overlap the extension via EX_VA in the first direction X and the second direction Y. That is, the extension via EX_VA may not completely pass through the cell substrate 100.

The extension via EX_VA may electrically connect the extension pad EX_PAD and the cell contact 150 to each other. In some example embodiments, the nonvolatile memory device according to some example embodiments may control the operation of the cell contact 150 using the extension via EX_VA and the extension pad EX_PAD. However, embodiments of the present disclosure are not limited thereto. In addition, in some example embodiments, the extension via EX_VA may be a passage for hydrogen ions (H⁺). Hydrogen ions (H⁺) may move through the extension via EX_VA. However, embodiments of the present disclosure are not limited thereto.

A portion of the extension via EX_VA may be provided in the insulating pattern 102 of the extension region R2. For example, as shown in FIG. 7, a bottom surface EX_VA_BS of the extension via EX_VA may be provided between the front surface 100a and the rear surface 100b of the cell substrate 100.

In some example embodiments, a portion of the extension via EX_VA may surround a portion of the cell contact 150. As an example, a level of the bottom surface EX_VA_BS of the extension via EX_VA may be different from a level of the upper surface 150US of the cell contact 150. A height from the rear surface 100b of the cell substrate 100 to the bottom surface EX_VA_BS of the extension via EX_VA may be greater than a height from the rear surface 100b of the cell substrate 100 to the upper surface 150US of the cell contact 150. However, embodiments of the present disclosure are not limited thereto.

In some example embodiments, a vertical length of the extension via EX_VA in the third direction Z may be the same as a vertical length of the input/output via IO_VA in the third direction Z. The extension via EX_VA and the input/output via IO_VA may be formed through the same process.

The cell via C_VA may be formed to pass through the upper insulating film 104 and the second interlayer insulating film 103. The cell via C_VA may be provided on the common source plate 101 of the cell array region R1. The cell via C_VA does not overlap the insulating pattern 102 in the third direction Z. The cell via C_VA overlaps the common source plate 101 in the third direction Z. In some example embodiments, the cell via C_VA may not overlap the cell substrate 100 in the first direction X and the second direction Y. For example, a bottom surface C_VA_BS of the cell via C_VA may be coplanar with a rear surface of the common source plate 101, that is, the rear surface 100b of the cell substrate 100. However, embodiments of the present disclosure are not limited thereto.

In some example embodiments, a vertical length of the cell via C_VA in the third direction Z may be less than the vertical length of the extension via EX_VA and the input/output via IO_VA in the third direction Z. Due to an etch selectivity of the common source plate 101 and the insulating pattern 102, the vertical length of the cell via C_VA may be less than the vertical length of the extension via EX_VA and the input/output via IO_VA.

The cell via C_VA may electrically connect the cell pad C_PAD and the common source plate 101 to each other. In some example embodiments, the cell via C_VA may be a passage of hydrogen ions (H⁺). Hydrogen ions (H⁺) may move through the cell via C_VA. However, embodiments of the present disclosure are not limited thereto. In addition, in some example embodiments, noise of the common source plate 101 can be reduced through the cell via C_VA.

The peripheral structure PERI may include a peripheral substrates 200, a lower insulating film 204, peripheral circuit elements PT, a third interlayer insulating film 240, line patterns 260 and 275, line contacts 255 and 265, a second input/output contact 270, and a second input/output pad 295.

The peripheral substrate 200 may include a front surface and a rear surface which are opposite to each other. The front surface of the peripheral substrate 200 may face the cell structure CELL. The rear surface of the peripheral substrate 200 may be opposite to the cell structure CELL.

The peripheral substrate 200 may include, for example, a semiconductor substrate such as a silicon substrate, a germanium substrate, or a silicon-germanium substrate. Alternatively, the peripheral substrate 200 may include a silicon-on-insulator (SOI) substrate, a germanium-on-insulator (GOI) substrate, or the like.

The peripheral circuit element PT may be formed on the peripheral substrate 200. The peripheral circuit element PT may be formed on the front surface of the peripheral substrate 200. The peripheral circuit element PT may constitute a peripheral circuit (for example, the peripheral circuit 30 of FIG. 1) which controls the operation of the nonvolatile memory device. For example, the peripheral circuit element PT may include a control logic (for example, the control logic 37 of FIG. 1), a row decoder (for example, the row decoder 33 of FIG. 1), and a page buffer (for example, the page buffer 35 of FIG. 1).

The peripheral circuit element PT may include, for example, a transistor, but the present disclosure is not limited thereto. For example, the peripheral circuit element PT may include not only various active elements such as a transistor but also various passive elements such as a capacitor, a resistor, and an inductor.

The lower insulating film 204 may be disposed on the rear surface of the peripheral substrate 200. The second input/output pad 295 may be disposed on the lower insulating film 204. The second input/output pad 295 may be connected to at least one of the peripheral circuit elements PT disposed in the peripheral structure PERI through the second input/output contact 270. The peripheral substrate 200 and the second input/output pad 295 may be separated by the lower insulating film 204.

The third interlayer insulating film 240 may be provided on the front surface of the peripheral substrate 200. The plurality of line patterns 260 and 275 and the plurality of line contacts 255 and 265 may be provided in the third interlayer insulating film 240. The third interlayer insulating film 240 may include an insulating material. For example, the third interlayer insulating film 240 may include at least one selected from among silicon oxide, silicon oxynitride, and a low-k material having a dielectric constant lower than that of silicon oxide, but the present disclosure is not limited thereto.

The plurality of line patterns 260 and 275 and the plurality of line contacts 255 and 265 may be electrically connected to each other. The peripheral circuit elements PT and the bit lines BL may be electrically connected to each other through the plurality of line patterns 260 and 275 and the plurality of line contacts 255 and 265. The plurality of line patterns 260 and 275 and the plurality of line contacts 255 and 265 may include a conductive material. The plurality of line patterns 260 and 275 and the plurality of line contacts 255 and 265 may include, for example, tungsten (W) or copper (Cu), but the present disclosure is not limited thereto.

The nonvolatile memory device according to some example embodiments may further include a first bonding metal 190 formed on an uppermost metal layer of the cell structure CELL and a second bonding metal 290 formed on an uppermost metal layer of the peripheral structure PERI.

The first bonding metal 190 and the second bonding metal 290 may be bonded to each other. Accordingly, a second surface CELL_b of the cell structure CELL and a third surface PERI_a of the peripheral structure PERI may be bonded to each other. When the first bonding metal 190 and the second bonding metal 290 are formed of copper (Cu), a bonding method may be a Cu—Cu bonding method.

The first bonding metal 190 may be connected to the bit line BL through a first bonding contact 185. The second bonding metal 290 may be connected to one of the peripheral circuit elements PT through a second bonding contact 285. Thus, the cell structure PERI and the peripheral structure CELL may be electrically connected to each other.

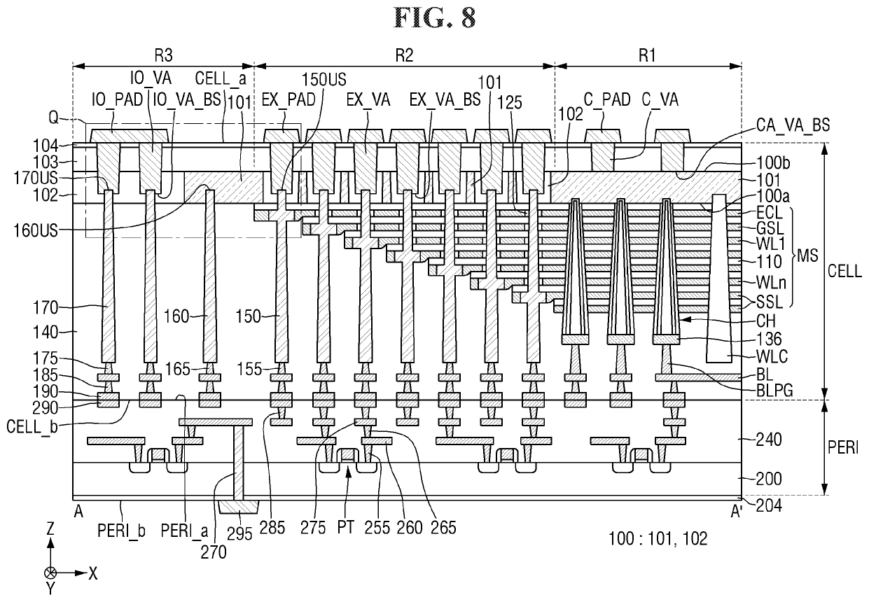

FIGS. 8 to 11 are views describing nonvolatile memory devices according to some example embodiments. FIGS. 8 to 11 may be cross-sectional views taken along the line A-A′ of FIG. 3. For convenience of description, content overlapping that described with reference to FIGS. 1 to 7 may be omitted.

First, referring to FIG. 8, a portion of a common source plate 101 may be provided in an extension region R2.

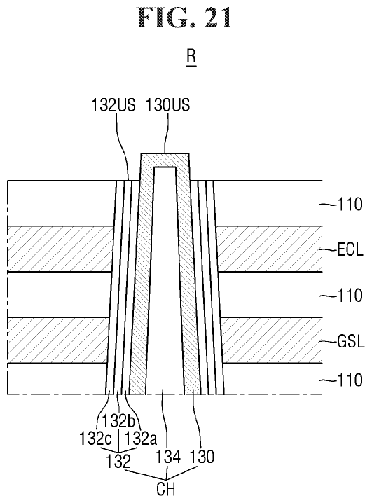

A cell substrate 100 may be formed by first forming a pre-common source plate 101P (see FIG. 21), etching the pre-common source plate 101P (see FIG. 21) to form a trench, and forming an insulating pattern 102 that fills the trench.

The common source plate 101 may be formed in the extension region R2 according to a mask used to etch the pre-common source plate 101P (see FIG. 21) to form the trench. In this case, an insulating pattern 102 overlaps a cell contact 150 and a first input/output contact 170 in a third direction Z. The common source plate 101 in the extension region R2 does not overlap the cell contact 150 in the third direction Z.

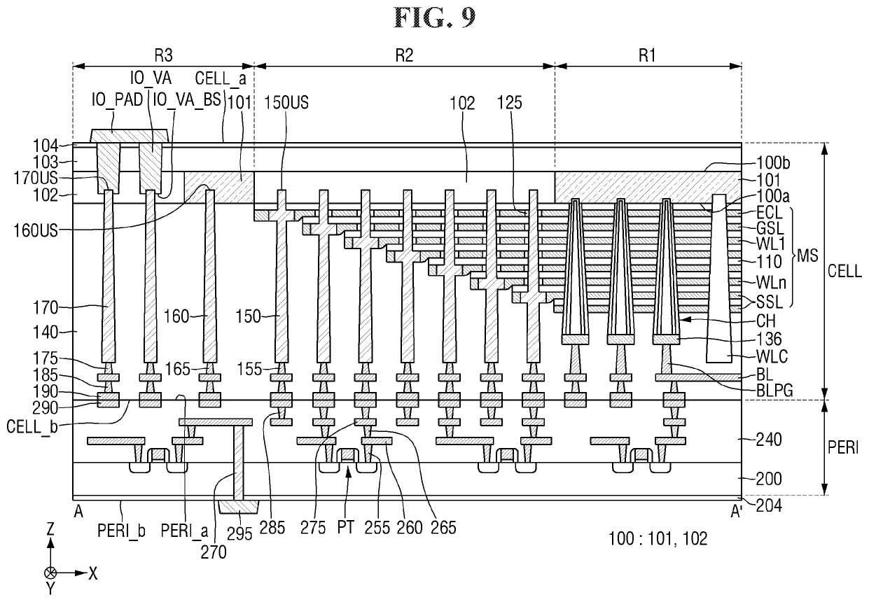

Referring to FIG. 9, a cell pad C_PAD, an extension pad EX_PAD, an extension via EX_VA, and a cell via C_VA may not be formed.

The cell via C_VA and the cell pad C_PAD may not be formed on the common source plate 101 of a cell array region R1. The extension via EX_VA and the extension pad EX_PAD may not be formed on the insulating pattern 102 of the extension region R2.

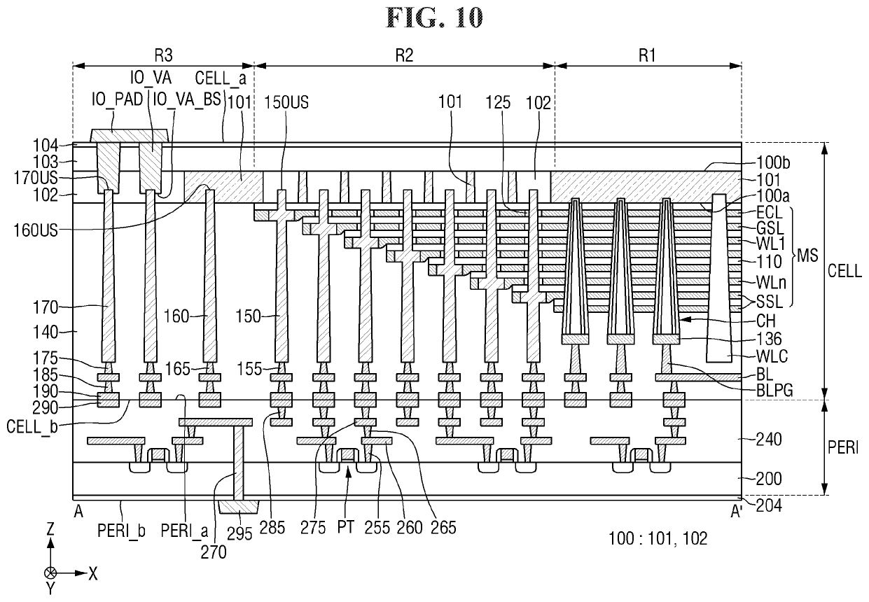

Referring to FIG. 10, the cell pad C_PAD, the extension pad EX_PAD, the extension via EX_VA, and the cell via C_VA may not be formed.

In addition, the common source plate 101 may be provided in the extension region R2. In the extension region R2, a width of the insulating pattern 102 in a first direction X is illustrated as gradually decreasing from a rear surface 100b of the cell substrate 100 toward a front surface 100a of the cell substrate 100, but the present disclosure is not limited thereto.

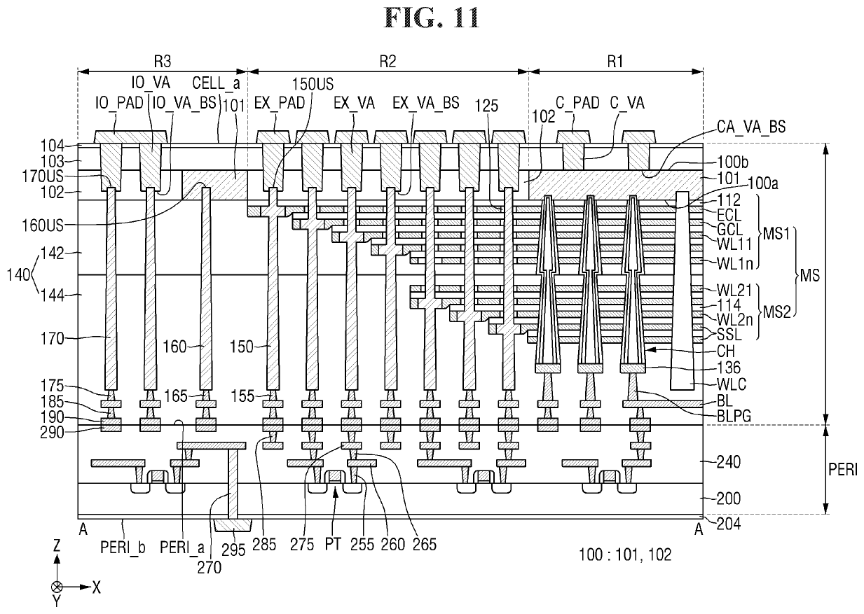

Referring to FIG. 11, the nonvolatile memory device according to some example embodiments may be a double stack nonvolatile memory device.

For example, a mold structure MS may include a lower mold structure MS1 and an upper mold structure MS2. The lower mold structure MS1 may be provided on the front surface 100a of the cell substrate 100. The upper mold structure MS2 may be provided on the lower mold structure MS1. The upper mold structure MS2 may be interposed between a peripheral structure PERI and the lower mold structure MS1.

Lower gate electrodes ECL, GSL, and WL11 to WL1n and lower mold insulating films 112 may be alternately stacked to constitute the lower mold structure MS1. Upper gate electrodes WL21 to WL2n and SSL and upper mold insulating films 114 may be alternately stacked to constitute the upper mold structure MS2. A channel structure CH may pass through the upper mold structure MS2 and the lower mold structure MS1 in the cell array region R1 in the third direction Z. Each of the lower mold insulating film 112 and the upper mold insulating film 114 may include an insulating material, for example, at least one selected from among silicon oxide, silicon nitride, and silicon oxynitride.

In some example embodiments, a first interlayer insulating film 140 may include a first lower interlayer insulating film 142 and a first upper interlayer insulating film 144. The first lower interlayer insulating film 142 may cover the lower mold structure MS1. The first upper interlayer insulating film 144 may be provided on the first lower interlayer insulating film 142. The first upper interlayer insulating film 144 may be interposed between the first lower interlayer insulating film 142 and the peripheral structure PERI. Each of the first lower interlayer insulating film 142 and the first upper interlayer insulating film 144 may include an oxide-based insulating material. Each of the first lower interlayer insulating film 142 and the first upper interlayer insulating film 144 may include, for example, at least one selected from among silicon oxide, silicon oxynitride, and a low-k material having a dielectric constant lower than that of silicon oxide, but the present disclosure is not limited thereto.

A cell contact 150 may pass through the first upper interlayer insulating film 144, the first lower interlayer insulating film 142, and the mold structure MS in the extension region R2. A source contact 160 may pass through the first upper interlayer insulating film 144 and the first lower interlayer insulating film 142 in a pad region R3. A first input/output contact 170 may pass through the first upper interlayer insulating film 144 and the first lower interlayer insulating film 142 in the pad region R3.

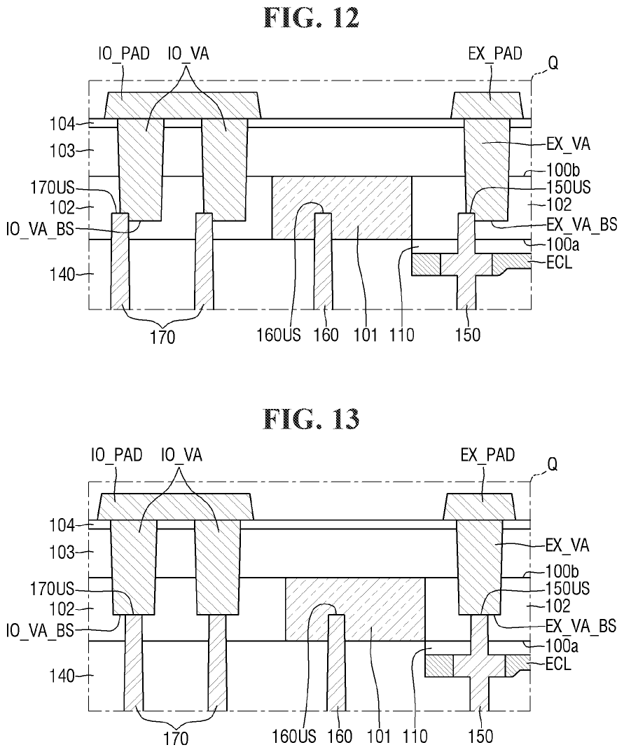

FIGS. 12 and 13 are views of a nonvolatile memory device according to some example embodiments. FIGS. 12 and 13 may be enlarged cross-sectional views of the region Q of FIG. 4. Content overlapping that described with reference to FIGS. 1 to 7 may be omitted.

First, referring to FIG. 12, an input/output via IO_VA and a first input/output contact 170 may be misaligned with each other in a third direction Z. The input/output via IO_VA and the first input/output contact 170 (e.g., centers of the input/output via IO_VA and the first input/output contact 170 in the first direction X) may not be aligned in the third direction Z and may be offset in the third direction Z.

An extension via EX_VA and a cell contact 150 may be misaligned with each other in the third direction Z. The extension via EX_VA and the cell contact 150 (e.g., centers of the extension via EX_VA and the cell contact 150 in the first direction X) may not be aligned in the third direction Z and may be offset in the third direction Z.

In some example embodiments, an upper surface 170US of the first input/output contact 170 may be in contact with an insulating pattern 102. The input/output via IO_VA may not cover a portion of the first input/output contact 170. An upper surface 150US of the cell contact 150 may be in contact with the insulating pattern 102. The extension via EX_VA may not cover a portion of the cell contact 150.

Referring to FIG. 13, the upper surface 170US of the first input/output contact 170 may be coplanar with a bottom surface IO_VA_BS of the input/output via IO_VA. In some embodiments, the bottom surface IO_VA_BS of the input/output via IO_VA may be flat and may contact the upper surface 170US of the first input/output contact 170 as illustrated in FIG. 13. Accordingly, the first input/output contact 170 may not include a portion that is in the input/output via IO_VA.

The input/output via IO_VA may not surround the first input/output contact 170. The input/output via IO_VA may not overlap the first input/output contact 170 in a first direction X.

The upper surface 150US of the cell contact 150 may be coplanar with the bottom surface IO_VA_BS of the input/output via IO_VA. The extension via EX_VA may not surround the cell contact 150. The extension via EX_VA may not overlap the cell contact 150 in the first direction X. In some embodiments, the upper surface 170US of the first input/output contact 170 and the upper surface 150US of the cell contact 150 may be coplanar with each other as illustrated in FIG. 13.

Hereinafter, a method of manufacturing a nonvolatile memory device according to some example embodiments of the present disclosure will be described.

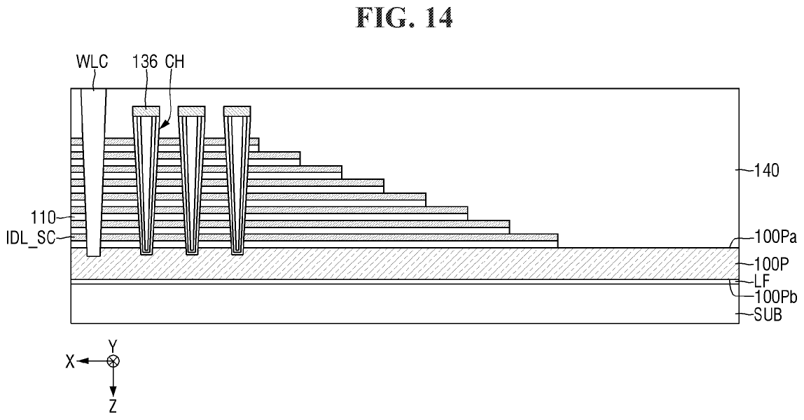

FIGS. 14 to 27 are views illustrating processes of manufacturing a nonvolatile memory device having a cross section of FIG. 4. In some embodiments, the processes illustrated in FIGS. 14 to 27 may be performed sequentially or may be performed in the order different from that illustrated in FIGS. 14 to 27.

Referring to FIG. 14, a substrate SUB is provided. The substrate SUB may be, for example, a wafer (e.g., a silicon wafer).

A liner film LF may be formed on the substrate SUB. The liner film LF may include titanium nitride (TiN), but the present disclosure is not limited thereto. A pre-cell substrate 100P may be formed on the liner film LF. The pre-cell substrate 100P may include a front surface 100Pa and a rear surface 100Pb which are opposite to each other. The rear surface 100Pb of the pre-cell substrate 100P may face the substrate SUB. The front surface 100Pa of the pre-cell substrate 100P may be opposite to the rear surface 100Pb. The pre-cell substrate 100P may include, for example, polysilicon.

A mold insulating film 110 and a mold sacrificial film ILD_SC may be alternately stacked on the front surface 100Pa of the pre-cell substrate 100P. The mold insulating film 110 and the mold sacrificial film ILD_SC may be stacked in a stair shape. The mold insulating film 110 may include an oxide-based insulating material. The mold sacrificial film ILD_SC may include a material having an etch selectivity with respect to the mold insulating film 110. For example, the mold sacrificial film ILD_SC may include a nitride-based insulating material. As an example, the mold sacrificial film ILD_SC may include silicon nitride (SiN), but the present disclosure is not limited thereto.

A channel structure CH may be formed to pass through the mold insulating film 110 and the mold sacrificial film ILD_SC. A channel pad 136 may be formed on the channel structure CH. A first interlayer insulating film 140 may be formed to cover the channel structure CH, the channel pad 136, the mold insulating film 110, and the mold sacrificial film ILD_SC.

A word line cutting structure WLC may be formed to pass through the first interlayer insulating film 140, the mold insulating film 110, and the mold sacrificial film ILD_SC.

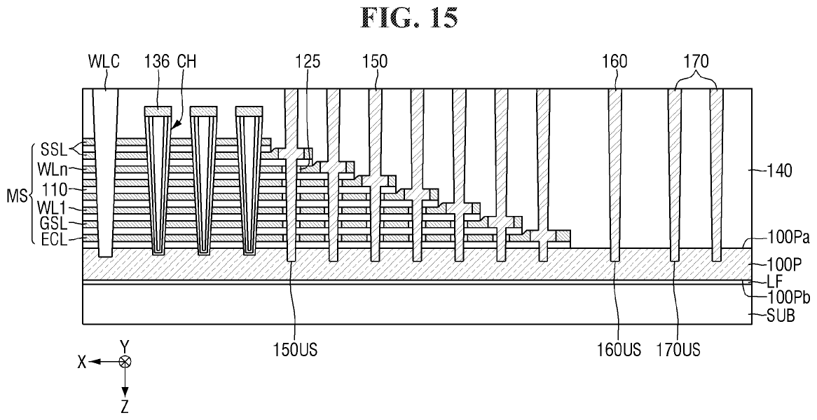

Referring to FIG. 15, a cell contact 150 may be formed. The cell contact 150 may be formed to pass through the first interlayer insulating film 140, the mold insulating film, and a mold sacrificial film ILD_SC. A portion of the cell contact 150 may be formed in the pre-cell substrate 100P. An upper surface 150US of the cell contact 150 may be provided between the front surface 100Pa and the rear surface 100Pb of the pre-cell substrate 100P. The upper surface 150US of the cell contact 150 may face the substrate SUB.

A source contact 160 may be formed. The source contact 160 may be formed to pass through the first interlayer insulating film 140. A portion of the source contact 160 may be formed in the pre-cell substrate 100P. An upper surface 160US of the source contact 160 may be provided between the front surface 100Pa and the rear surface 100Pb of the pre-cell substrate 100P. The upper surface 160US of the source contact 160 may face the substrate SUB.

A first input/output contact 170 may be formed. The first input/output contact 170 may be formed to pass through the first interlayer insulating film 140. A portion of the first input/output contact 170 may be formed in the pre-cell substrate 100P. An upper surface 170US of the first input/output contact 170 may be provided between the front surface 100Pa and the rear surface 100Pb of the pre-cell substrate 100P. The upper surface 170US of the first input/output contact 170 may face the substrate SUB.

Subsequently, gate electrodes ECL, GSL, WL1 to WLn, and SSL may be formed. The gate electrodes ECL, GSL, WL1 to WLn, and SSL may be formed through a replacement process. The mold sacrificial film ILD_SC may be removed, and the gate electrodes ECL, GSL, WL1 to WLn, SSL may be formed in a space in which the mold sacrificial film ILD_SC is removed.

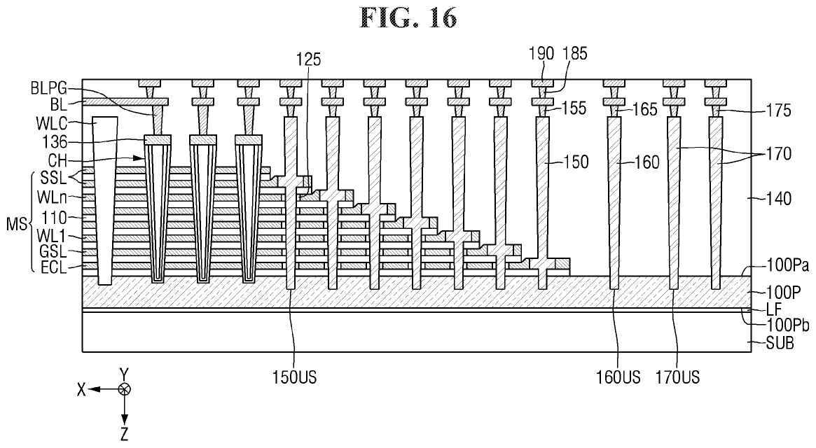

Referring to FIG. 16, a bit line contact plug BLPG, a bit line BL, a first contact 155, a second contact 165, a third contact 175, a first bonding contact 185, and a first bonding metal 190 may be formed.

The bit line contact plug BLPG, the first contact 155, the second contact 165, and the third contact 175 may be formed. The bit line contact plug BLPG may be connected to the channel pad 136. The first contact 155 may be connected to the cell contact 150. The second contact 165 may be connected to the source contact 160. The third contact 175 may be connected to the first input/output contact 170.

Subsequently, the bit line BL may be formed. The bit line BL may extend in a second direction Y. The bit line BL may be connected to the bit line contact plug BLPG, the first contact 155, the second contact 165, and the third contact 175.

Next, the first bonding contact 185 and the first bonding metal 190 may be formed (e.g, may be sequentially formed). The first bonding contact 185 and the first bonding metal 190 may be connected to the bit line BL. The first bonding metal 190 may define a second surface CELL_b of a cell structure.

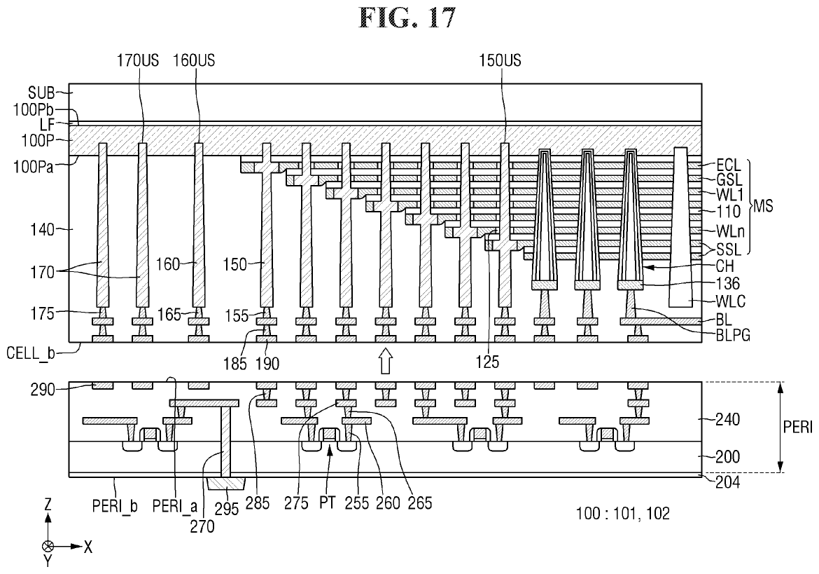

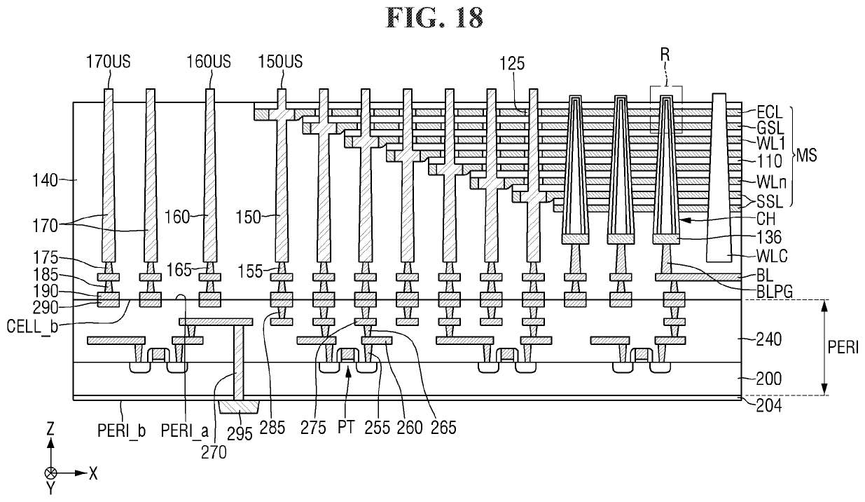

Referring to FIG. 17, a peripheral structure PERI may be provided. The peripheral structure PERI may be the same as the peripheral structure PERI described with reference to FIG. 4.

The peripheral structure PERI includes a third surface PERI_a and a fourth surface PERI_b which are opposite to each other. The second surface CELL_b of a cell structure CELL may face the third surface PERI_a of the peripheral structure PERI. The first bonding metal 190 and a second bonding metal 290 may be bonded to each other. The cell structure CELL to be formed later and the peripheral structure PERI may be electrically connected to each other through the first bonding metal 190 and the second bonding metal 290.

Referring to FIG. 18, the substrate SUB, the liner film LF, and the pre-cell substrate 100P may be removed.

The pre-cell substrate 100P may be removed to expose a portion of the first input/output contact 170, a portion of the source contact 160, a portion of the cell contact 150, a portion of the channel structure CH, and a portion of the word line cutting structure WLC.

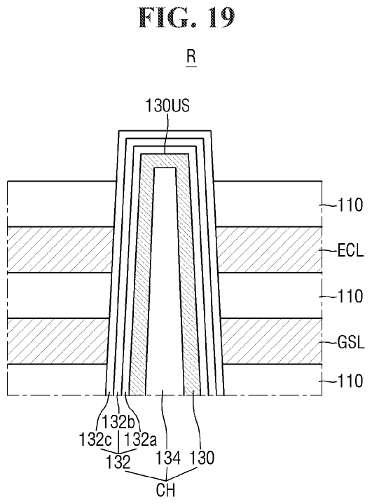

FIG. 19 is an enlarged cross-sectional view of the region R of FIG. 18.

Referring to FIG. 19, the pre-cell substrate 100P may be removed to expose a portion of the channel structure CH. A portion of an information storage film 132 of the channel structure CH may be exposed.

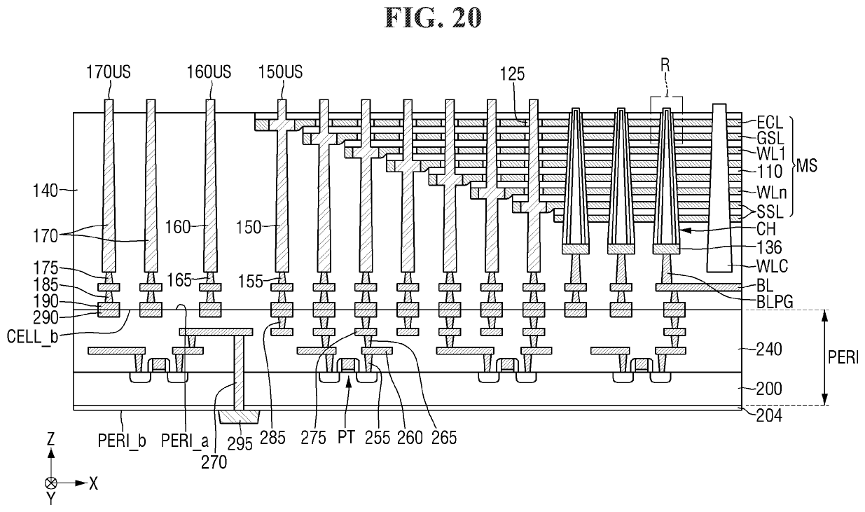

FIG. 21 is an enlarged cross-sectional view of the region R of FIG. 20.

Referring to FIGS. 20 and 21, the exposed portion of the information storage film 132 may be removed. As a result, a semiconductor pattern 130 may be exposed. An upper surface 130US of the semiconductor pattern 130 and a portion of a sidewall of the semiconductor pattern 130 may be exposed.

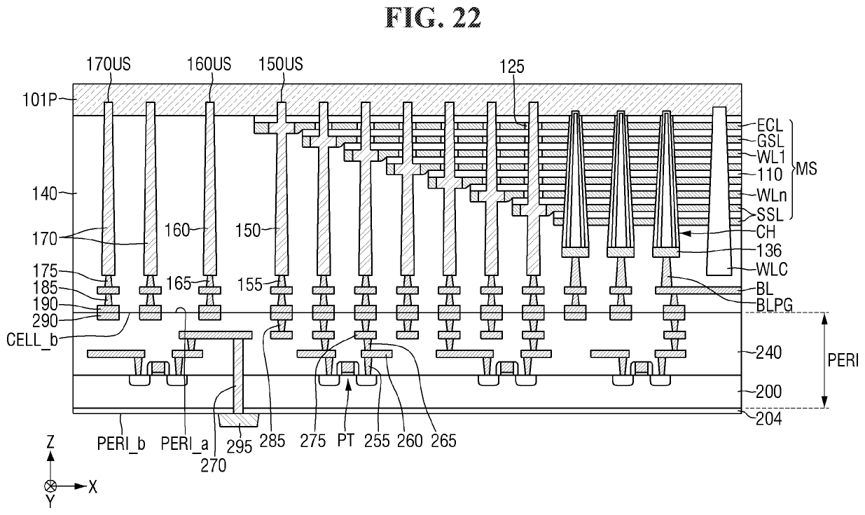

Referring to FIG. 22, a pre-common source plate 101P may be formed. The pre-common source plate 101P may cover the exposed first input/output contacts 170, source contact 160, cell contact 150, channel structure CH, and word line cutting structure WLC. The pre-common source plate 101P may be in contact with the exposed semiconductor pattern 130. The pre-common source plate 101P may include doped polysilicon or a metal, but the present disclosure is not limited thereto.

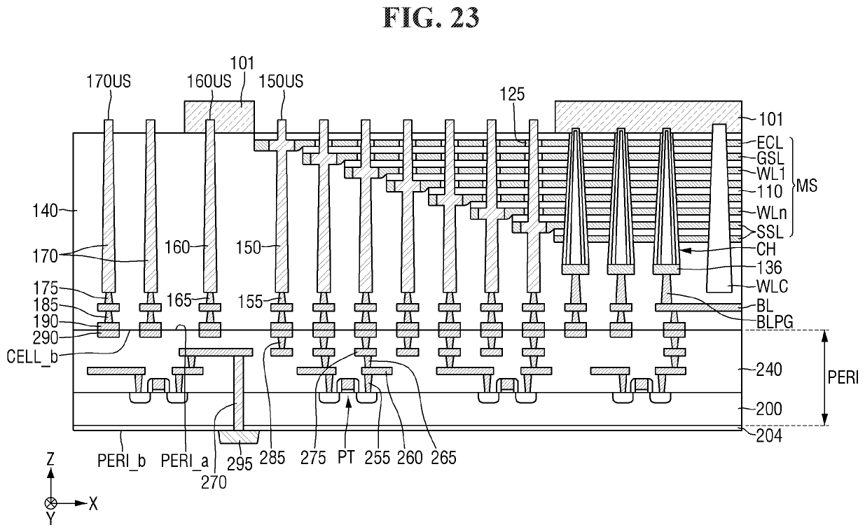

Referring to FIG. 23, a common source plate 101 may be formed by etching the pre-common source plate 101P.

Portions of the first input/output contact 170 and the cell contact 150 may be exposed by etching the pre-common source plate 101P. The common source plate 101 may be connected to the source contact 160 and the channel structure CH. The common source plate 101 does not overlap the cell contact 150 and the first input/output contact 170 in a third direction Z.

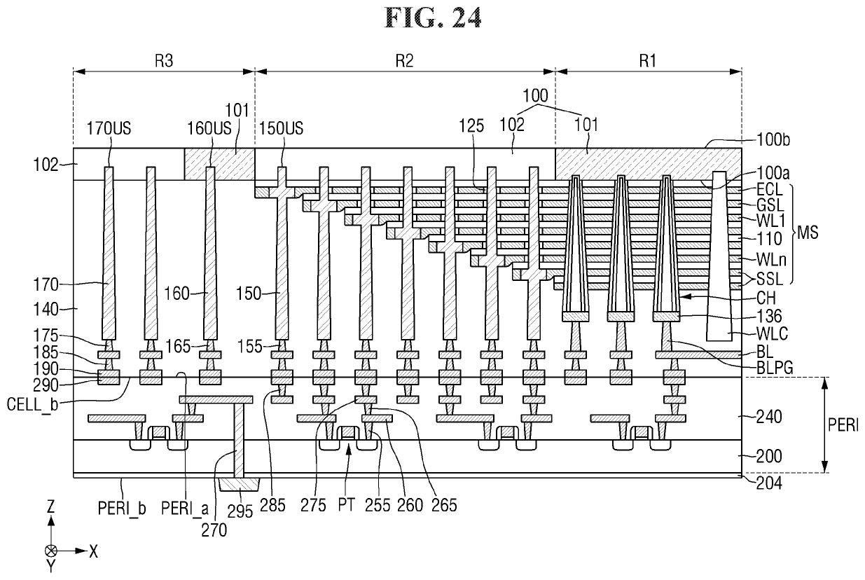

Referring to FIG. 24, an insulating pattern 102 may be formed. The insulating pattern 102 may cover the exposed first input/output contact 170 and cell contact 150. The insulating pattern 102 may be formed between the common source plates 101. The common source plate 101 and the insulating pattern 102 may constitute a cell substrate 100.

The cell substrate 100 may include portions that are respectively included in a cell array region R1, an extension region R2, and a pad region R3. The common source plate 101 may be disposed in the cell array region R1. The common source plate 101 may not be disposed in the extension region R2. The insulating pattern 102 may be disposed in the extension region R2. The common source plate 101 may be disposed in a portion of the pad region R3. The insulating pattern 102 may be disposed in another portion of the pad region R3.

The cell substrate 100 may include a front surface 100a and a rear surface 100b which are opposite to each other. The front surface 100a of the cell substrate 100 may be in contact with the first interlayer insulating film 140 or the mold insulating film 110. An upper surface 170US of the first input/output contact 170 may be provided between the front surface 100a and the rear surface 100b of the cell substrate 100. An upper surface 150US of the cell contact 150 may be provided between the front surface 100a and the rear surface 100b of the cell substrate 100.

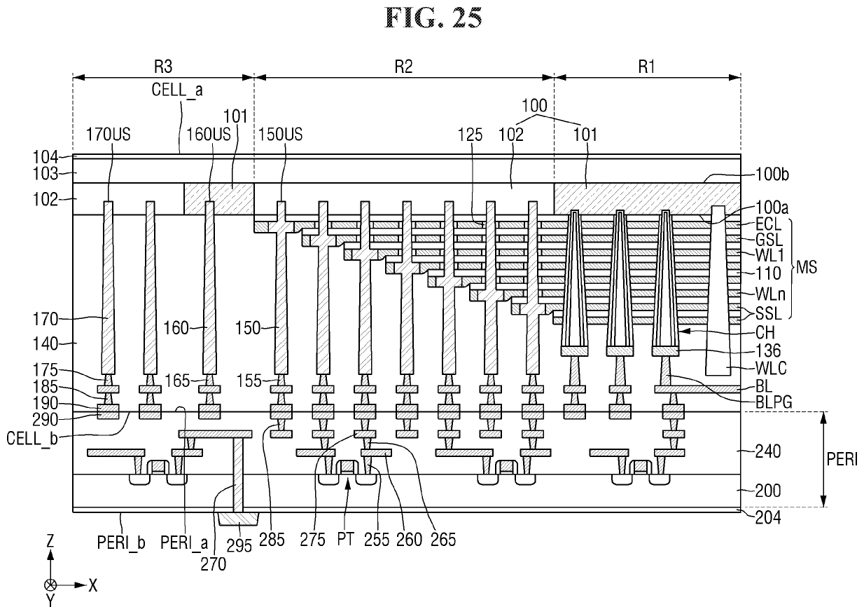

Referring to FIG. 25, a second interlayer insulating film 103 and an upper insulating film 104 may be formed on the rear surface 100b of the cell substrate 100.

The second interlayer insulating film 103 may be formed on the rear surface 100b of the cell substrate 100. The upper insulating film 104 may be formed on the second interlayer insulating film 103. An upper surface of the upper insulating film 104 may define a first surface CELL_a of the cell structure.

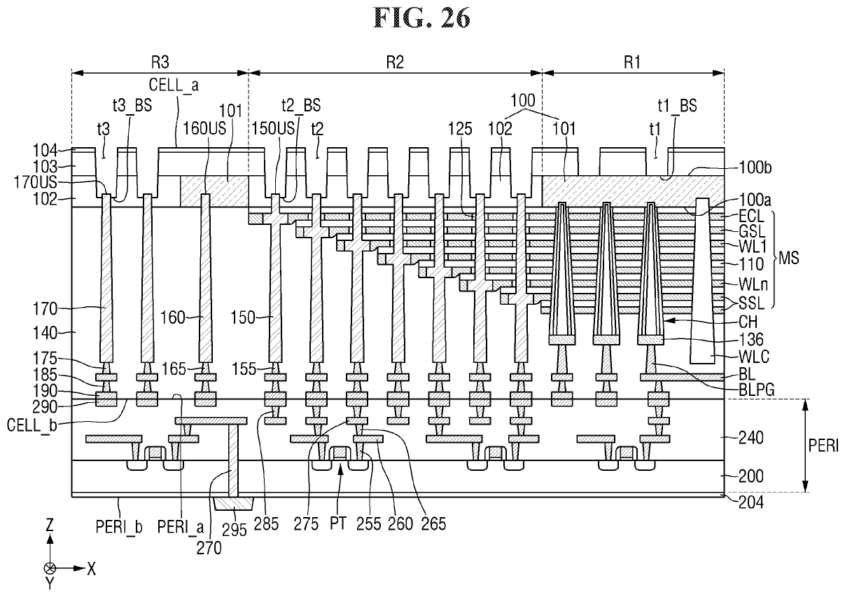

Referring to FIG. 26, a first trench t1 may be formed to pass through the upper insulating film 104 and the second interlayer insulating film 103. The cell substrate 100 may be etched to form second and third trenches t2 and t3 to pass through the upper insulating film 104 and the second interlayer insulating film 103.

The first trench t1 may be formed in the cell array region R1. The first trench t1 may be a trench for forming a cell via C_VA. A bottom surface t1_BS of the first trench t1 may be coplanar with the rear surface 100b of the cell substrate 100.

The second trench t2 may be formed in the extension region R2. The second trench t2 may be a trench for forming an extension via EX_VA. A bottom surface t2_BS of the second trench t2 may be provided between the front surface 100a and the rear surface 100b of the cell substrate 100. The second trench t2 may expose the upper surface 150US of the cell contact 150. The second trench t2 may expose a portion of a sidewall of the cell contact 150.

The third trench t3 may be formed in the pad region R3. The third trench t3 may be a trench for forming an input/output via IO_VA. A bottom surface t3_BS of the third trench t3 may be provided between the front surface 100a and the rear surface 100b of the cell substrate 100. The third trench t3 may expose the upper surface 170US of the first input/output contact 170. The third trench t3 may expose a portion of a sidewall of the first input/output contact 170.

In some example embodiments, the bottom surface t2_BS of the second trench t2 and the bottom surface t3_BS of the third trench t3 may be coplanar with each other. The second trench t2 and the third trench t3 may be formed through the same process. In some example embodiments, a vertical depth of the second trench t2 and the third trench t3 in the third direction Z may be greater than a vertical depth of the first trench t1 in the third direction Z. The first to third trenches t1, t2, and t3 may be formed through the same process, but the common source plate 101 and the insulating pattern 102 may have an etch selectivity. Accordingly, the vertical depths of the second trench t2 and the third trench t3 in the third direction Z may be greater than the vertical depth of the first trench t1 in the third direction Z.

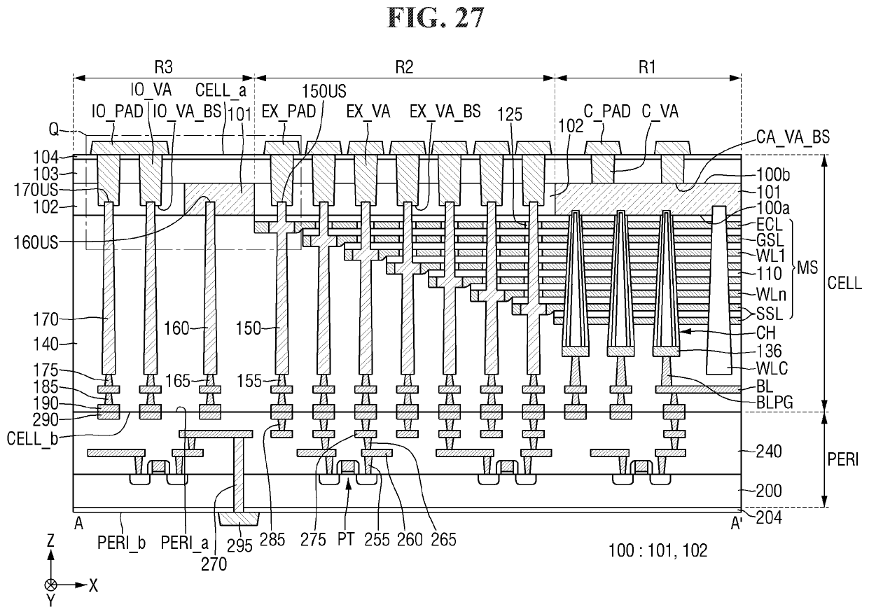

Referring to FIG. 27, the cell via C_VA may be formed to fill the first trench t1. The extension via EX_VA may be formed to fill the second trench t2. The input/output via IO_VA may be formed to fill the third trench t3.

Subsequently, a cell pad C_PAD may be formed to be connected to the cell via C_VA. An extension pad EX_PAD may be formed to be connected to the extension via EX_VA. A first input/output pad IO_PAD may be formed to be connected to the input/output via IO_VA.

Accordingly, the cell structure CELL may be formed. The cell structure CELL may be the same as the cell structure CELL described with reference to FIG. 4.

Hereinafter, an electronic system including a nonvolatile memory device according to example embodiments will be described with reference to FIGS. 1 to 7 and FIGS. 28 to 30.

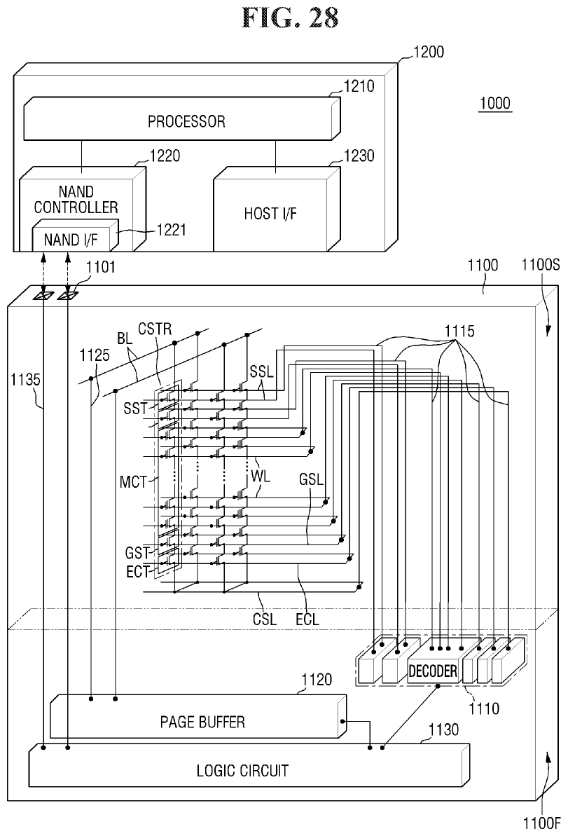

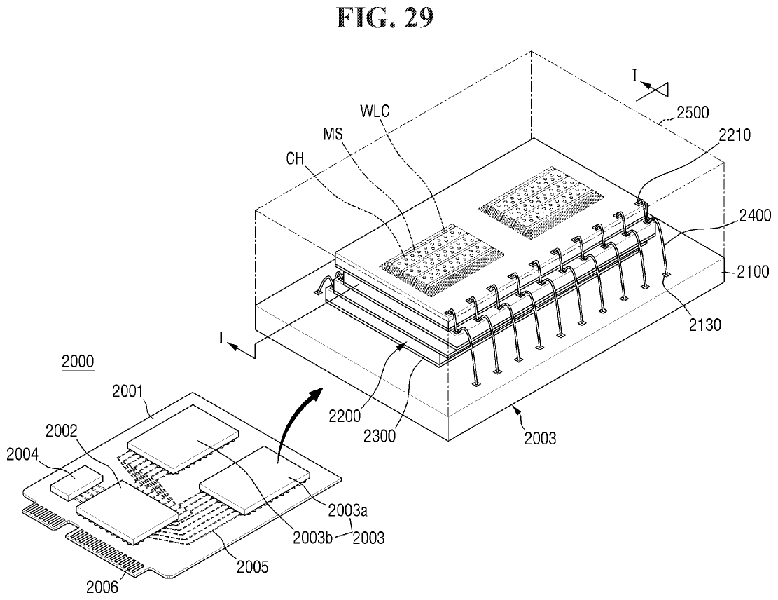

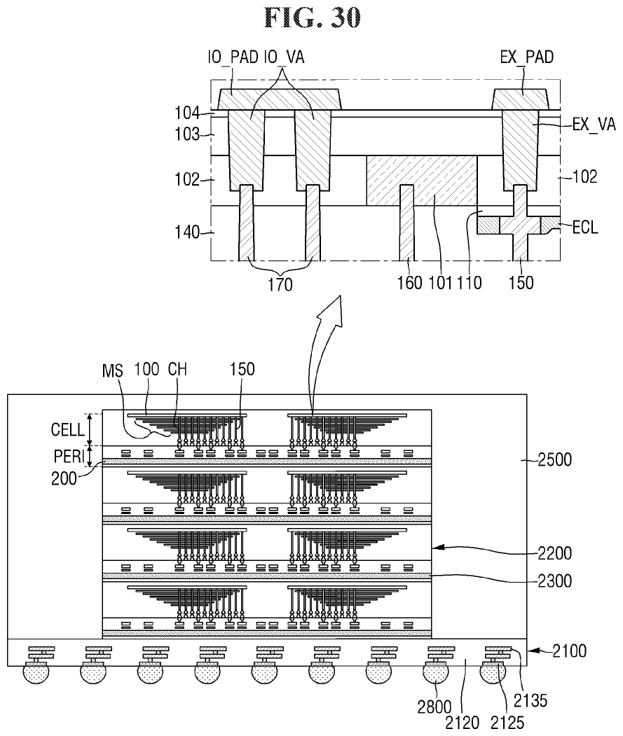

FIG. 28 is an example block diagram illustrating an electronic system according to some example embodiments. FIG. 29 is an example perspective view for describing the electronic system according to some example embodiments. FIG. 30 is a schematic cross-sectional view along the line I-I of FIG. 29.

Referring to FIG. 28, an electronic system 1000 according to some example embodiments may include a nonvolatile memory device 1100 and a controller 1200 electrically connected to the nonvolatile memory device 1100. The electronic system 1000 may be a storage device including one or more nonvolatile memory devices 1100 or an electronic device including storage devices. For example, the electronic system 1000 may be a solid state drive device (SSD) device, a Universal Serial Bus (USB) device, a computing system, a medical device, or a communication device including one or more nonvolatile memory devices 1100.

The nonvolatile memory device 1100 may be, for example, a NAND flash memory device, for example, the nonvolatile memory device described above with reference to FIGS. 1 to 7. The nonvolatile memory device 1100 may include a first structure 1100F and a second structure 1100S on the first structure 1100F.

The first structure 1100F may be a peripheral circuit structure including a decoder circuit 1110 (for example, the row decoder 33 of FIG. 1), a page buffer 1120 (for example, the page buffer 35 of FIG. 1), and a logic circuit 1130 (for example, the control logic 37 of FIG. 1).

The second structure 1100S may include the common source line CSL, the plurality of bit lines BL, and the plurality of cell strings CSTR described above with reference to FIG. 2. The cell strings CSTR may be connected to the decoder circuit 1110 through a word line WL, at least one string selection line SSL, and at least one ground selection line GSL. In addition, the cell strings CSTR may be connected to the page buffer 1120 through the bit lines BL.

In some example embodiments, the common source line CSL and the cell strings CSTR may be electrically connected to the decoder circuit 1110 through first connection lines 1115 extending from the first structure 1100F to the second structure 1100S.

In some example embodiments, the bit lines BL may be electrically connected to the page buffer 1120 through second connection lines 1125 extending from the first structure 1100F to the second structure 1100S.

The nonvolatile memory device 1100 may communicate with a controller 1200 through an input/output pad 1101 electrically connected to the logic circuit 1130 (for example, the control logic 37 of FIG. 1). The input/output pad 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In some example embodiments, the electronic system 1000 may include the plurality of nonvolatile memory devices 1100, and in this case, the controller 1200 may control the plurality of nonvolatile memory devices 1100.

The processor 1210 may control the overall operation of the electronic system 1000 including the controller 1200. The processor 1210 may operate according to certain firmware and may access the nonvolatile memory device 1100 by controlling the NAND controller 1220. The NAND controller 1220 may include a NAND interface 1221 which performs communication with the nonvolatile memory device 1100. A control command for controlling the nonvolatile memory device 1100, data to be written to memory cell transistors MCT of the nonvolatile memory device 1100, and data to be read from the memory cell transistors MCT of the nonvolatile memory device 1100 may be transmitted through the NAND interface 1221. The host interface 1230 may provide a communication function between the electronic system 1000 and an external host. When a control command is received from the external host through the host interface 1230, the processor 1210 may control the nonvolatile memory device 1100 in response to the control command.

Referring to FIGS. 28 to 30, the electronic system according to some example embodiments may include a main board 2001, a main controller 2002 mounted on the main board 2001, at least one semiconductor package 2003, and a dynamic random access memory (DRAM) 2004. The semiconductor package 2003 and the DRAM 2004 may be connected to the main controller 2002 through line patterns 2005 formed on the main board 2001.

The main board 2001 may include a connector 2006 including a plurality of pins coupled to the external host. The number and arrangement of the plurality of pins in the connector 2006 may vary according to a communication interface between the electronic system 2000 and the external host. In some example embodiments, the electronic system 2000 may communicate with the external host according to any one of interfaces such as a USB, Peripheral Component Interconnect Express (PCI-Express), Serial Advanced Technology Attachment (ATA), and M-Phy for Universal Flash Storage (UFS). In some example embodiments, the electronic system 2000 may operate with power received from the external host through the connector 2006. The electronic system 2000 may further include a power management integrated circuit (PMIC) for distributing power received from the external host to the main controller 2002 and the semiconductor package 2003.

The main controller 2002 may write data to or read data from the semiconductor package 2003 and may improve an operating speed of the electronic system 2000.

The DRAM 2004 may be a buffer memory for reducing a speed difference between the external host and the semiconductor package 2003 that is a data storage space. The DRAM 2004 included in the electronic system 2000 may operate as a type of a cache memory and may provide a space for temporarily storing data in an operation of controlling the semiconductor package 2003. When the electronic system 2000 includes the DRAM 2004, the main controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b which are spaced from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package board 2100, the semiconductor chips 2200 on the package board 2100, adhesive layers 2300 disposed on lower surfaces of the semiconductor chips 2200, connection structures 2400 electrically connecting the semiconductor chips 2200 and the package board 2100, and a molding layer 2500 covering the semiconductor chips 2200 and the connection structures 2400 on the package board 2100.

The package board 2100 may be a printed circuit board including package upper pads 2130. Each semiconductor chip 2200 may include an input/output pad 2210. The input/output pad 2210 may correspond to the input/output pad 1101 of FIG. 28.

In some example embodiments, the connection structures 2400 may be bonding wires electrically connecting the input/output pads 2210 and the package upper pads 2130. Accordingly, in each of the first semiconductor package 2003a and the second semiconductor package 2003b, the semiconductor chips 2200 may be electrically connected to each other through a bonding wire method and may be electrically connected to the package upper pads 2130 of the package board 2100. In some example embodiments, in each of the first semiconductor package 2003a and the second semiconductor package 2003b, the semiconductor chips 2200 may be electrically connected to each other through a connection structure including a through-electrode (through-silicon via (TSV)) instead of the connection structure 2400 in a bonding wire type.

In some example embodiments, the main controller 2002 and the semiconductor chips 2200 may be included in one package. In some example embodiments, the main controller 2002 and the semiconductor chips 2200 may be mounted on a separate interposer board different from the main board 2001, and the main controller 2002 and the semiconductor chips 2200 may be connected to each other through lines formed on the interposer board.

In some example embodiments, the package board 2100 may be a printed circuit board. The package board 2100 may include a package board body 2120, package upper pads 2130 disposed on an upper surface of the package board body 2120, lower pads 2125 disposed on or exposed through a lower surface of the package board body 2120, and internal lines 2135 electrically connecting the upper pads 2130 and the lower pads 2125 in the package board body 2120. The upper pads 2130 may be electrically connected to the connection structures 2400. As shown in FIG. 29, the lower pads 2125 may be connected to the lines patterns 2005 of the main board 2001 of the electronic system 2000 through conductive connectors 2800.

Referring to FIGS. 29 and 30, in the electronic system according to some example embodiments, each of the semiconductor chips 2200 may include the nonvolatile memory device described above with reference to FIGS. 1 to 7. For example, each of the semiconductor chips 2200 may include a peripheral structure PERI and a cell structure CELL. For example, the peripheral structure PERI may include the peripheral substrate 200 and the peripheral circuit element PT described above with reference to FIGS. 3 to 7. In addition, for example, the cell structure CELL may include the cell substrate 100, the mold structure MS, the channel structure CH, the word line cutting structure WLC, the bit line BL, and the cell contact 150 described above with reference to FIGS. 3 to 7.

As used herein, an element or region that is “covering” or “surrounding” or “filling” another element or region may completely or partially cover or surround or fill the other element or region. Further, as used herein used herein the term “and/or” includes any and all combinations of one or more of the associated listed items.

In concluding the detailed description, those skilled in the art will appreciate that many variations and modifications may be made to the embodiments described herein without substantially departing from the principles of the present disclosure. Therefore, the embodiments described herein are used in a generic and descriptive sense only and not for purposes of limitation.

What is claimed is:

1. A nonvolatile memory device comprising:
a cell substrate including portions respectively included in a cell array region, an extension region, and a pad region of the nonvolatile memory device, the cell substrate including a front surface and a rear surface opposite to each other and including a common source plate and an insulating pattern;
a mold structure on the front surface of the cell substrate and including a plurality of gate electrodes and a plurality of mold insulating films, wherein the plurality of gate electrodes and the plurality of mold insulating films include respective first portions, and the first portions of the plurality of gate electrodes and the first portions of the plurality of mold insulating films are alternately stacked in the cell array region, and wherein the plurality of gate electrodes and the plurality of mold insulating films further include respective second portions, and the second portions of the plurality of gate electrodes and the second portions of the plurality of mold insulating films are alternately stacked in a stair shape in the extension region;
a channel structure that extends through the mold structure in the cell array region and is connected to the common source plate;
a cell contact that extends through the mold structure in the extension region and is connected to at least one of the plurality of gate electrodes;
a first interlayer insulating film that is on the front surface of the cell substrate and extends on the mold structure;
a second interlayer insulating film on the rear surface of the cell substrate;
an input/output pad on the second interlayer insulating film in the pad region;
an input/output contact extending through the first interlayer insulating film in the pad region; and
an input/output via that includes portions respectively in the second interlayer insulating film and the cell substrate in the pad region and connects the input/output contact and the input/output pad to each other,
wherein the common source plate does not overlap the cell contact and the input/output contact in a first direction that is perpendicular to the front surface of the cell substrate.

2. The nonvolatile memory device of claim 1, wherein the common source plate is not in the extension region.

3. The nonvolatile memory device of claim 1, wherein an upper surface of the cell contact is between the front surface of the cell substrate and the rear surface of the cell substrate.

4. The nonvolatile memory device of claim 1, wherein an upper surface of the input/output contact is between the front surface of the cell substrate and the rear surface of the cell substrate.

5. The nonvolatile memory device of claim 1, wherein:
the channel structure includes an information storage film and a semiconductor pattern; and
an upper surface of the semiconductor pattern is connected to the common source plate.

6. The nonvolatile memory device of claim 5, wherein an upper surface of the information storage film is coplanar with the front surface of the cell substrate.

7. The nonvolatile memory device of claim 5, wherein the upper surface of the semiconductor pattern is between the front surface of the cell substrate and the rear surface of the cell substrate.

8. The nonvolatile memory device of claim 1, further comprising a source contact that extends through the first interlayer insulating film in the pad region and is connected to the common source plate.

9. The nonvolatile memory device of claim 1, further comprising:
a cell pad on the second interlayer insulating film in the cell array region; and
a cell via that extends through the second interlayer insulating film on the common source plate in the cell array region and connects the common source plate and the cell pad to each other,
wherein a bottom surface of the cell via is coplanar with the rear surface of the cell substrate.

10. The nonvolatile memory device of claim 9, wherein a length of the cell via in the first direction is shorter than a length of the input/output via in the first direction.

11. The nonvolatile memory device of claim 1, further comprising:
an extension pad on the second interlayer insulating film in the extension region; and
an extension via that extends through the second interlayer insulating film in the extension region, includes a portion in the insulating pattern of the cell substrate, and connects the cell contact and the extension pad to each other,
wherein a bottom surface of the extension via is coplanar with a bottom surface of the input/output via.

12. A nonvolatile memory device comprising:
a cell structure including a first surface and a second surface opposite to each other; and
a peripheral structure contacting the cell structure and including a third surface contacting the second surface and a fourth surface opposite to the third surface,
wherein the cell structure includes:
a cell substrate including portions respectively included in a cell array region, an extension region, and a pad region of the nonvolatile memory device, the cell substrate including a front surface and a rear surface opposite to each other and including a common source plate and an insulating pattern, wherein the front surface of the cell structure faces the peripheral structure;
a mold structure on the front surface of the cell substrate and including a plurality of gate electrodes and a plurality of mold insulating films, wherein the plurality of gate electrodes and the plurality of mold insulating films include respective first portions, and the first portions of the plurality of gate electrodes and the first portions of the plurality of mold insulating films are alternately stacked in the cell array region, and wherein the plurality of gate electrodes and the plurality of mold insulating films further include respective second portions, and the second portions of the plurality of gate electrodes and the second portions of the plurality of mold insulating films are alternately stacked in a stair shape in the extension region;
a channel structure that extends through the mold structure in the cell array region and is connected to the common source plate;
a cell contact that extends through the mold structure in the extension region and is connected to at least one of the plurality of gate electrodes;
a first interlayer insulating film that is on the front surface of the cell substrate and extends on the mold structure;
an input/output contact extending through the first interlayer insulating film in the pad region;
a second interlayer insulating film on the rear surface of the cell substrate;
a cell pad on the second interlayer insulating film in the cell array region;
an extension pad on the second interlayer insulating film in the extension region;
an input/output pad on the second interlayer insulating film in the pad region;
a cell via that extends through the second interlayer insulating film on the common source plate in the cell array region and connects the common source plate and the cell pad to each other;
an extension via that includes portions respectively in the second interlayer insulating film and the insulating pattern in the extension region and connects the cell contact and the extension pad to each other; and
an input/output via that includes portions respectively in the second interlayer insulating film and the cell substrate in the pad region and connects the input/output contact and the input/output pad to each other,
wherein:
a bottom surface of the extension via and a bottom surface of the input/output via are between the front surface of the cell substrate and the rear surface of the cell substrate;
the insulating pattern overlaps the cell contact and the input/output contact in a first direction that is perpendicular to the front surface of the cell substrate; and
the common source plate does not overlap the cell contact and the input/output contact in the first direction.

13. The nonvolatile memory device of claim 12, wherein the common source plate is not in the extension region.

14. The nonvolatile memory device of claim 12, wherein a length of the cell via in the first direction is less than a length of the input/output via in the first direction.

15. The nonvolatile memory device of claim 12, wherein an upper surface of the cell contact is between the front surface of the cell substrate and the rear surface of the cell substrate.

16. The nonvolatile memory device of claim 12, wherein an upper surface of the input/output contact is between the front surface of the cell substrate and the rear surface of the cell substrate.

17. The nonvolatile memory device of claim 12, wherein:
the channel structure includes an information storage film and a semiconductor pattern; and
an upper surface of the semiconductor pattern is connected to the common source plate.

18. The nonvolatile memory device of claim 17, wherein:
an upper surface of the information storage film is coplanar with the front surface of the cell; and
the upper surface of the semiconductor pattern is between the front surface of the cell substrate and the rear surface of the cell substrate.

19. The nonvolatile memory device of claim 17, further comprising a source contact that extends through the first interlayer insulating film in the pad region and is connected to the common source plate.

20. An electronic system comprising:
a main board;
a nonvolatile memory device on the main board; and
a controller electrically connected to the nonvolatile memory device on the main board,
wherein the nonvolatile memory device includes:
a cell substrate including portions respectively included in a cell array region, an extension region, and a pad region of the nonvolatile memory device, the cell substrate including a front surface and a rear surface opposite to each other and including a common source plate and an insulating pattern;
a mold structure on the front surface of the cell substrate and including a plurality of gate electrodes and a plurality of mold insulating films, wherein the plurality of gate electrodes and the plurality of mold insulating films include respective first portions, and the first portions of the plurality of gate electrodes and the first portions of the plurality of mold insulating films are alternately stacked in the cell array region, and wherein the plurality of gate electrodes and the plurality of mold insulating films further include respective second portions, and the second portions of the plurality of gate electrodes and the second portions of the plurality of mold insulating films are alternately stacked in a stair shape in the extension region;
a channel structure that extends through the mold structure in the cell array region and is connected to the common source plate;
a cell contact that extends through the mold structure in the extension region and is connected to at least one of the plurality of gate electrodes;
a first interlayer insulating film that is on the front surface of the cell substrate and extends on the mold structure;
a second interlayer insulating film on the rear surface of the cell substrate;
an input/output pad on the second interlayer insulating film in the pad region;
an input/output contact extending through the first interlayer insulating film in the pad region; and
an input/output via that includes portions respectively in the second interlayer insulating film and the cell substrate in the pad region and connects the input/output contact and the input/output pad to each other,
wherein the insulating pattern does not overlap the cell contact and the input/output contact in a vertical direction.
